(19) United States
(12) Patent Application Publication
(10) Pub. No.: US 2024/0331993 A1
(43) Pub. Date: Oct. 3, 2024

(54) CHARGED PARTICLE SPECTROMETER

(71) Applicant: Scienta Omicron AB, Uppsala (SE)

(72) Inventor: Patrik KARLSSON, Uppsala (SE)

(73) Assignee: Scienta Omicron AB, Uppsala (SE)

(21) Appl. No.: 18/693,037

(22) PCT Filed: Sep. 7, 2022
(86) PCT No.: PCT/SE2022/050793

§ 371 Date: Mar. 18, 2024

(30) Foreign Application Priority Data
Sep. 21, 2021 (SE) 2151151-4

(51) Int. Cl. H01J 49/22; H01J 49/00; H01J 49/02; H01J 49/44

(52) U.S. Cl. CPC H01J 49/22; H01J 49/0004; H01J 49/025; H01J 49/44

(57) ABSTRACT

A charged particle spectrometer is described, which comprises an imaging energy analyser and an electrostatic lens system, having a first deflector and optionally a second deflector operable to cause deflection of the charged particles in a coordinate direction a first and, if applicable, also a second time before the entrance into the imaging energy analyser. The spectrometer also comprises a control unit which is configured to control the nominal spatial position of the electrostatic lens system and to control the scanning in an angular mode of the spectrometer using a lens table. A computer program for controlling the control unit is also described.

### CROSS-REFERENCE TO RELATED APPLICATIONS

This application is a U.S. national stage application under 35 U.S.C. 371 of International Application No. PCT/SE2022/050793, filed Sep. 7, 2022, which claims the priority of SE Application No. 2151151-4, filed Sep. 21, 2021. The entire contents of each priority application is incorporated herein by reference.

### FIELD OF THE DISCLOSURE

The present invention relates to a charged particle spectrometer comprising an imaging energy analyser, an electrostatic lens system having an optical axis, and a control unit configured to control the voltages applied to the imaging energy analyser and the various elements of the electrostatic lens system. Moreover, it relates to a computer program configured to control the spectrometer function by means of a control unit.

The charged particle spectrometer is operable in an angular mode, in which charged particles from a sample are imaged at an imaging plane essentially at the position of an entrance slit to the imaging energy analyser. The positions of the charged particles at the imaging plane are in the first order approximation linearly dependent on the emission angles of the charged particles from the sample. Additionally, start angles in the direction perpendicular to the slit are accessed using an angular deflection method.

### BACKGROUND OF THE DISCLOSURE

In several scientific disciplines, it is of interest to perform angularly resolved spectroscopy of charged particles emitted from an emission spot of a sample. The charged particles that are emitted from a small area of such a sample may be studied using spatially-resolved angle-resolved photoemission spectroscopy, hereinafter denoted spatially-resolved ARPES. One of the techniques for performing spatially-resolved ARPES is to illuminate a small emission spot on the sample with a light source to induce emission of charged particles from the emission spot. The experimental setup includes a spectrometer, in which typically a hemispherical energy analyser operates with a lens system, the lens system being configured to form a particle beam of charged particles from the sample. However, to be able to perform spatially-resolved ARPES of the emission spot with sufficient precision, it is necessary to position the emission spot correctly in relation to the lens system.

The position of the emission spot is dependent on the alignment of the light source and the sample relative to the spectrometer. In the prior art, the emission spot has most commonly been aligned mechanically on the optical axis of the lens system and at the correct working distance from the lens system. The number of different parameters makes precise alignment tedious and very difficult to achieve, due to the small size of the emission spot. Furthermore, precise and non-coupled mechanical movement of each component in many directions comes at a high cost, and even if such movement could be implemented, the mechanical hysteresis would be very difficult to avoid and predict. However, for relatively large emission spots, i.e. a size in the order of millimetres, the alignment with sufficient precision may be performed mechanically.

However, in spatially-resolved ARPES, the size of the emission spot is typically smaller than the width (Wₑ) of the slit, and for this situation mechanical alignment has severe shortcomings partly mentioned above. For a spectrometer operated in the angular mode, with the slit arranged in a plane normal to the optical axis and positioned at the entrance of the hemispherical energy analyser, a misaligned emission spot produces undesired disturbance. The sources of disturbance may be intensity artefacts and spectral shifts, both of which are difficult to interpret or counteract by the operator of the spectrometer. This is particularly the case when start angles in the direction perpendicular to the slit are accessed using an angular deflection method as disclosed in WO 2013/133739 A9. Therefore, precise alignment of the lens system will be both difficult and time consuming. Due to the life span of samples for used for ARPES measurements generally, which is typically short, it is crucial for the performance of the spectrometer that a precise alignment of the sample and the lens and deflector arrangements can be made swiftly. If not, there is a clear risk for degradation of the sample to be analysed, making measurements impossible.

JP2015036670A describes an electron spectrometer, which comprises a pre-stage deflection element disposed between a pre-stage lens and an aperture for deflecting electrons. With such an electron spectroscopy apparatus, it is possible to deflect photoelectrons emitted from an area of a sample located outside the optical axis of the optical system constituting the electron pickup portion to align with the optical axis. This allows photoelectrons emitted from any area of the sample to be measured. By means of such an electron spectrometer, it is possible to align the photoelectrons emitted from various regions of the sample with the optical axis of the optical system that constitutes the electron capture unit. The emission spot according to the disclosure of JP2015036670A may cover the entire sample or a certain region of the sample. No distinction is made regarding using the electron spectrometer with an emission spot covering the entire sample or an emission spot covering a specific region of the sample. Hence, the emission spot does not need to be aligned with the optical axis of the electron spectrometer. The region to be analysed is selected in two dimensions by adjusting voltages in the pre-stage deflection element. In a subsequent step, the angularly resolved spectrum is recorded using an electrostatic system. Hence, the spectrometer and method rely on a mechanical separation of the problem, which can only reach a certain level of approximation and hence a certain level of precision. Furthermore, numerous mechanical boundary conditions limit the design of the spectrometer and its components.

As a result of the above, there is a need for an improved spectrometer and a method for such a spectrometer for recording a high-quality spectrum for situations when the size of the emission spot is smaller than the width of the slit.

### SUMMARY OF THE DISCLOSURE

In view of the above, an objective of the present disclosure is to present a charged particle spectrometer, which resolves at least one of the perceived drawbacks associated with charged particle spectrometers for deflecting charged particles in a direction perpendicular to an optical axis, according to the prior art.

Another objective of the present disclosure is to present a computer program comprising instructions which, when executed by a processor of the control unit, configures the control unit to control the above spectrometer such that at least one of the perceived drawbacks associated with a charged particle spectrometer according to the prior art is resolved.

Yet another objective of the present disclosure is to present a charged particle spectrometer, and a computer program for controlling the charged particle spectrometer, the spectrometer comprising at least one deflector for deflecting the charged particles in a direction perpendicular to an optical axis in an electrostatic lens system of the spectrometer, for recording a high quality spectrum when the size of the emission spot is smaller than the width of the slit used at the entrance of an analysing region of the spectrometer.

At least one of these objectives is fulfilled by means of a charged particle spectrometer and a computer program according to the independent claims. Further advantages are achieved by means of the features of the dependent claims.

According to a first aspect of the invention, a charged particle spectrometer operable in angular mode is provided. The spectrometer comprises an imaging energy analyser having a first end with an entrance for charged particles, and a second end with an at least two-dimensional multichannel particle detector. At least one entrance slit extends in a slit direction and is arranged at the entrance for selecting the charged particles to enter the imaging energy analyser.

An electrostatic lens system extends along an optical axis, arranged to transport charged particles emitted from a sample to the entrance of the imaging energy analyser, the electrostatic lens system comprising at least a first lens element at a first end arranged to face the sample, a last lens element at a second end arranged to face the entrance of the imaging energy analyser, at least one intermediate lens element arranged in-between the first lens element and the last lens element, and at least a first deflector operable to cause deflection of the charged particles in a direction perpendicular to the optical axis of the electrostatic lens system before entry into the imaging energy analyser.

A control unit is further configured to control the voltages to be applied to the imaging energy analyser and the electrostatic lens system, and is characterised in that the control unit is provided with a lens table comprising a set of individual output voltage settings to be applied on each lens element and each deflector of the electrostatic lens system. Wherein at least one voltage setting is defined by at least three parameters, a first parameter defining a nominal spatial position of an emission spot on the sample in one dimension relative to the optical axis, a second parameter defining an acceleration potential of the electrostatic lens system, and a third parameter defining the direction of emission of the charged particles from the sample.

The set of output voltage settings specifies the voltages to be applied on the electrostatic lens system for modulating the deflection of charged particles from the nominal spatial position defined by the first parameter, with an acceleration potential defined by the second parameter and in the emission angle defined by the third parameter. This makes it possible to control a selected particle beam trajectory of charged particles to enter into the entrance slit of the imaging energy analyser with a minimised divergence in the direction (a) across the slit at the slit plane.

By means of such a spectrometer, it is possible to accurately position, without using a mechanical positioning device, the nominal spatial position to the position of an emission spot from which charged particles are emitted. The electronic positioning of the nominal spatial position affects what voltages to be applied on the electrostatic lens system for perfect alignment. The lens table enables the setting of an optimal set of output voltage settings on the electrostatic lens system. The different sets of voltages for the different output voltage settings may have been calculated theoretically in advance.

A zero nominal spatial position is typically the nominal spatial for the electrostatic lens system with a predetermined zero setting of the electrostatic lens element and no deflection by the first deflector and possible additional deflector arrangements. A second deflector arrangement is optional and disclosed in accordance with an alternative embodiment of the present invention. This alternative embodiment has enough degrees of freedom for controlling the particle beam in a large operational range. The nominal spatial position should be set to the actual position of the emission spot. The set of output voltages for a specific setting point is not a superposition of the voltages for setting the nominal position to the position defined by the setting point and the set of voltages for the specific emission angle when the nominal spatial position is at the zero nominal spatial position.

More specifically, a first set of difference voltages may be defined as the set of differences between the set of voltages to position the nominal spatial position of the emission spot at position y along the y-axis for the emission angle θ_{y}=0°, in the plane perpendicular to the slit direction, and the set of voltages to position the nominal spatial position of the emission spot at zero along the y-axis for the emission angle θ_{y}=0°, in the plane perpendicular to the slit direction. A second set of difference voltages may be defined as the set of differences between the set of voltages to position the nominal spatial position of the emission spot at zero along the y-axis for the emission angle θ_{y}=10°, in the plane perpendicular to the slit direction, and the set of voltages to position the nominal spatial position of the emission spot at zero along the y-axis for the emission angle θ_{y}=0°, in the plane perpendicular to the slit direction. The set of voltages calculated by superposition would then position the nominal spatial position of the emission spot at zero along the y-axis for the emission angle θ_{y}=0°, in the plane perpendicular to the slit direction, the first set of difference voltages and the second set of difference voltages. However, such a superposition would not result in an optimal imaging and would prevent an optimal resolution.

The higher resolution achievable with the spectrometer according to the first aspect is achievable when the charged particles are emitted from an emission spot of the sample, having a largest diameter that is smaller than the width (Wₑ) of the entrance slit. For emission spots that are considerably larger than the width of the entrance slit, the gain in resolution by means of the spectrometer according to the first aspect is more limited.

A further advantage of the invention is that the parametrisation of empirical adjustment parameters adjusts the elements through a bounded function based on a model. This implies that integrity of the angular mode operation is maintained, which means that the positions of the charged particles at the imaging plane are in the first order approximation linearly dependent on the emission angles of the charged particles from the sample. Furthermore, this allows an operator to interpret and adjust alignment of the charged particle spectrometer in a manner that was previously not possible, particularly when utilising the spectrometer in the angular mode.

According to an alternative embodiment of the invention, the electrostatic lens system further comprises a second deflector operable to cause deflection of the charged particles in a direction perpendicular to the optical axis at least a second time before entry into the imaging energy analyser. By this is achieved an alignment of the twice deflected particle beam with the optical axis in one direction (y) that allows the particle beam to enter into the entrance slit of the imaging energy analyser with a minimised divergence in the direction (α) across the slit at the slit plane. This allows both intensity and resolution of the imaging energy analyser to be maintained also for charged particles having start angles towards the optical axis of up to 20 or more degrees. The ability to utilise such a large interval of start angles is an improvement compared to the maximum of a few degrees allowed in the general case without utilisation of two subsequent deflections. In this context, it is to be mentioned that deflections of the charged particles may be made using any known technology, including magnetic deflectors, mechanical tilting of the lens or lens arrangement, various methods for causing of electrostatic deflection by altering the deflector potential etc., i.e. for deflecting charged particles from their intended trajectory in a spectrometer. However, the preferred embodiment for highly resolved angular measurements relies on electrostatic deflection means without any mechanical movement. This allows measurement schemes including a pre-defined sequence of deflection settings without any mechanical movement to be performed swiftly, accurately, and with high repeatability.

According to one embodiment of the invention, the output voltage settings are configured in that at least two non-mutually mirror symmetric elements have individual voltage settings, wherein each setting is defined in a non-separable manner by at least three parameters for controlling at least one selected trajectory associated with the selected condition.

The output voltage settings for controlling at least one selected trajectory associated with the selected parameters may be defined by a set of continuous functions of the selected parameters. This provides a further advantage over a lens table having discretely predefined setting positions, even though the setting positions may be distributed closely, in the proximity of each other and in several dimensions.

Furthermore, the value of any of the said parameters may be continuously selected within upper and lower boundary conditions, and the output voltage settings for each element of the electrostatic lens system may be defined as a continuous function of the parameters. The lens table specifies the voltages to be applied on the elements of the electrostatic lens system for controlling at least one selected trajectory associated with the selected parameters.

The nominal spatial position may be obtained in many different ways. The nominal spatial position may be set by a user or may be obtained using an automatic alignment procedure. Examples on how the setting point may be obtained will follow. The nominal spatial position is set at the actual position of the emission spot.

The first parameter may define the nominal spatial position in the direction transverse to the slit direction. This direction coincides with the extension of the slit width (Wₑ), which in turn sometimes also is referred to as the energy dispersive direction. The correct positioning of the nominal spatial position in the direction transverse to the direction of extension of the entrance slit is important for the achievement of high resolution. When the first parameter defines the nominal spatial position in the direction transverse to the direction of extension of the entrance slit, this is suitably implemented in an ordinary Cartesian coordinate system.

The setting point may be defined also by a fourth parameter, which defines a nominal spatial position in a second dimension. Apart from the nominal spatial position of the emission spot in the direction transverse to the slit direction, an important direction to control is the nominal spatial position of the emission spot along the optical axis. To this end, the fourth parameter may define the spatial position in the direction along the optical axis of the electrostatic lens system.

The output voltage settings may be defined by at least five parameters, of which three parameters defines the nominal spatial position of an emission spot on the sample in three dimensions in relation to the optical axis and to the first lens element. By having three parameters defining the nominal spatial position, it is possible to position the nominal spatial position of the emission spot in a volume. It is straightforward to define the position of the spatial parameters in Cartesian coordinates, but polar coordinates are also possible.

According to one alternative embodiment, the position of the nominal spatial position of the emission spot is first optimized in the direction transverse to the slit direction and subsequently in the direction along the optical axis and finally along the slit direction. The optimization in each direction may be performed as iterations by moving a small distance in one direction and then evaluating the spectrum from that position until an optimum spectrum is recorded. According to another alternative embodiment, the alignment is optimised by arranging that the spectrometer throughput for a positive emission angle in the plane perpendicular to the slit direction is symmetric with the spectrometer throughput for a negative emission angle in the plane perpendicular to the slit direction. Such measurement scheme can be interpreted when measuring at an energy position without angular dispersion. Alternatively, computer algorithms for enhancing the non-dispersive background could be utilised.

The configuration of the imaging energy analyser and the multichannel particle detector determines the energy window of the multichannel particle detector. The concept of pass energy is well-known in the field. The highest energy of the charged particles that needs to be managed by the electrostatic lens system is the pass energy plus half of the energy window. The lowest energy of the charged particles that needs to be managed by the electrostatic lens system is the pass energy minus half of the energy window. The retardation ratio is defined as the ratio between the median kinetic energy of the charged particles at the sample in the chosen energy window and the pass energy. For low retardation ratios, this means that the energy window is large in comparison to the median kinetic energy of the charged particles at the sample, and thus that charged particles with very different kinetic energy need to be controlled by the electrostatic lens. Due to chromatic aberration, it is difficult to control charged particles with a large difference in kinetic energy as charged particles having different kinetic energies will focus differently within the lens system. Without changing the retardation ratio, but controlling an additional parameter defining a shift from the detector centre in the energy direction, it is possible to prioritise and to control particles with low energies for a first part of a spectrum, with medium energies for a second part of the spectrum, and with high energies for a third part of the spectrum. The total spectrum is then obtainable by merging the first, the second and the third spectra. In the general case, any energy level (E_{kPRio}) within the detector window can be prioritised. In addition, acquisition algorithms based on scanning energy levels within the energy window are valuable if overlaid on an alignment functionality. This because weighted summations of spectra would produce strong artefacts if the emission spot would be misaligned.

The setting point may be defined also by an angle parameter, which defines the emission angle of the charged particles, in the plane of the entrance slit in relation to the optical axis, which emission angle is to be prioritised at the multichannel particle detector. Such a parameter is of particular importance when the spectrometer is arranged with a large retardation ratio of the charged particles.

At large retardation ratios, the charged particles will be strongly retarded in the lens system. This will inevitably increase the total divergence of the particle beam, implying that the rate of change of the divergence around the selected working point increases. Charged particles associated with trajectories different form the selected trajectory might not be imaged correctly on the multichannel particle detector. This may lead to spectra of poor quality or missing spectra for large emission angle offsets. However, by prioritising a certain emission angle, in the plane of the entrance slit in relation to the optical axis, which is not zero, it is possible to improve the spectrum for large emission angle components θₓ at the cost of the quality of the spectra for small emission angle components θₓ.

In accordance with an alternative embodiment of the invention, it has been found to be beneficial to introduce a lens table that is also dependent on an additional parameter defining an angular shift from the trajectory associated with the detector centre, the shift being an angular component (θₓ) in the coordinate (x) direction along the slit, and by changing that parameter alone modulates the lens table, such that any angular level (θ_{xPrio}) within the detector window can be selected to be associated with the selected particle trajectory. In analogy with the previous discussion regarding energy levels, advanced acquisition algorithms based on scanning angular levels within the detector window in the angular dispersive direction would only be truly valuable if overlaid on an alignment functionality. This is because weighted summations of spectra would produce strong artefacts if the emission spot would be misaligned.

According to a second aspect of the present invention, a computer program is provided for controlling a charged particle spectrometer operable in angular mode. The spectrometer comprises an imaging energy analyser having a first end with an entrance for charged particles, and a second end with an at least two-dimensional multichannel particle detector. At least one entrance slit, extending in a slit direction, is arranged at the entrance for selecting the charged particles to enter the imaging energy analyser.

An electrostatic lens system extends along an optical axis and is arranged to transport charged particles emitted from a sample to the entrance of the imaging energy analyser. The electrostatic lens system comprises at least a first lens element at a first end arranged to face the sample, a last lens element at a second end arranged to face the entrance of the imaging energy analyser, at least one intermediate lens element arranged in-between the first lens element and the last lens element, and at least a first deflector operable to cause deflection of the charged particles in at least a first coordinate direction perpendicular to the optical axis of the electrostatic lens system before entry into the imaging energy analyser.

A control unit, comprising a processor, is configured to control the voltages to be applied to the imaging energy analyser and the electrostatic lens system, and is characterised in that it further comprises instructions, which, when executed by the processor: configures the control unit to be provided with a lens table comprising a set of individual output voltage settings to be applied on each lens element and each deflector of the electrostatic lens system, wherein at least one voltage setting is defined by at least three parameters, a first parameter defining a nominal spatial position of an emission spot on the sample in one dimension relative to the optical axis, a second parameter defining an acceleration potential of the electrostatic lens system, and a third parameter defining the direction of emission of the charged particles from the sample, wherein the set of output voltage settings specifies the voltages to be applied on the electrostatic lens system for modulating the deflection of charged particles from the nominal spatial position defined by the first parameter, with an acceleration potential defined by the second parameter and in the emission angle defined by the third parameter, so as to control a selected particle beam trajectory of charged particles to enter into the entrance slit of the imaging energy analyser with a minimised divergence in the direction (u) across the slit at the slit plane.

The lens table is stored in a memory, which is accessible by the processor. The memory may be integrated with the control unit or be an external memory. An external memory may be a cloud-based memory or a remote physical memory.

The computer program makes it possible to accurately position, without using a mechanical positioning device, the nominal spatial position of the emission spot to the position of an actual emission spot from which charged particles are emitted. The electronic positioning of the nominal spatial position of the emission spot affects what voltages to be applied on the electrostatic lens system for perfect alignment. The lens table enables an optimal set of output voltage settings on the electrostatic lens system. The different sets of voltages for the different set points may be calculated theoretically in advance.

In the following, preferred embodiments of the invention will be described with reference to the drawings.

### BRIEF DESCRIPTION OF THE FIGURES

FIG. 1 shows schematically a charged particle spectrometer with an imaging energy analyser and an electrostatic lens system.

FIG. 2 shows the cross-section A-A of the imaging energy analyser in FIG. 1 and the positions of the multichannel particle detector.

FIG. 3 shows in cross section the electrostatic lens system of FIG. 1 and a sample.

FIG. 4 shows in larger detail the sample and the first end of the electrostatic lens system.

FIG. 5 shows in larger detail the sample and a coordinate system.

FIG. 6 illustrates how charged particles are deflected and imaged onto the imaging plane of the electrostatic lens system of the spectrometer in its angular mode of operation.

FIG. 7 illustrates the trajectory of a charged particle through the entrance slit of the imaging energy analyser.

FIG. 8 illustrates how an angular offset of the trajectory from perpendicular to the slit affects the radial offset on the multichannel detector.

FIG. 9A illustrates the position of the charged particles at the entrance slit, when voltages have been applied to the electrostatic lens such that the emission angle in the plane perpendicular to the slit direction θ_{y}=0° is positioned on the entrance slit in the angular mode and when the electrostatic lens is optimally aligned.

FIG. 9B illustrates the angular offset at the entrance slit as a function of the position along the slit and across the slit, when the spectrometer is set for detection of a first angle in the angular mode.

FIG. TOA illustrates the position of the charged particles at the entrance slit, when voltages have been applied to the electrostatic lens such that the emission angle in the plane perpendicular to the slit direction θ_{y}=10° is positioned on the entrance slit in the angular mode and when the electrostatic lens is optimally aligned.

FIG. 10B illustrates the angular offset at the entrance slit as a function of the position along the slit and across the slit, with the settings of FIG. 10A.

FIG. 11A illustrates in larger detail the position of the charged particles at the entrance slit, when voltages have been applied to the electrostatic lens such that the emission angle in the plane perpendicular to the slit direction θ_{y}=10° is positioned on the entrance slit in the angular mode and when the electrostatic lens is optimally aligned.

FIG. 11B illustrates the angular offset at the entrance slit as a function of the position along the slit and across the slit, for the settings according to FIG. 11A.

FIG. 12A illustrates in larger detail the position of the charged particles at the entrance slit, when voltages have been applied to the electrostatic lens such that the emission angle in the plane perpendicular to the slit direction θ_{y}=10° is positioned on the entrance slit in the angular mode and when the electrostatic lens is misaligned in a first direction.

FIG. 12B illustrates the angular offset at the entrance slit as a function of the position along the slit and across the slit, for the settings according to FIG. 12A.

FIG. 13 illustrates the angular offset at the entrance slit as a function of the position along the slit and across the slit, for the θ_{y} selection and misalignment according to FIGS. 12A and 12B, when the electrostatic lens is electronically aligned with set of voltages from a lens table.

FIG. 14 illustrates the angular offset at the entrance slit as a function of the position along the slit and across the slit, for the θ_{y} selection and misalignment according to FIGS. 12A and 12B, when the electrostatic lens is electronically aligned using superposition.

FIG. 15 illustrates the angular offset at the entrance slit as a function of the position along the slit when voltages have been applied to the electrostatic lens such that the emission angle in the plane perpendicular to the slit direction θ_{y}=−10° is positioned on the entrance slit in the angular mode and when the electrostatic lens is optimally aligned.

FIG. 16 illustrates the angular offset at the entrance slit as a function of the position along the slit and across the slit, when voltages have been applied to the electrostatic lens such that the emission angle θ_{y}=−10°, in the plane perpendicular to the slit direction 30, is positioned on the entrance slit in the angular mode and when the electrostatic lens is misaligned −0.3 mm in the y-direction.

FIG. 17 illustrates the angular offset α at the entrance slit as a function of the position along the slit and across the slit, for the θ_{y} selection and misalignment according to FIG. 16, when the electrostatic lens is electronically aligned with a set of voltages from a lens table.

FIG. 18 illustrates the angular offset α at the entrance slit as a function of the position along the slit and across the slit, for the θ_{y} selection and misalignment according to FIG. 16, when the electrostatic lens is electronically aligned using superposition.

FIG. 19 illustrates the angular offset at the entrance slit as a function of the position along the slit and across the slit, when voltages have been applied to the electrostatic lens such that the emission angle in the plane perpendicular to the slit direction θ_{y}=10° is positioned on the entrance slit in the angular mode and when the electrostatic lens is misaligned in a second direction.

FIG. 20 illustrates the angular offset at the entrance slit as a function of the position along the slit and across the slit, when the spectrometer is set for detection according to FIG. 19 and when the electrostatic lens is electronically aligned in the second direction with set of voltages from the lens table.

FIG. 21 illustrates the angular offset at the entrance slit as a function of the position along the slit and across the slit, when the spectrometer is set for detection according to FIG. 19 and when the electrostatic lens is electronically aligned using superposition.

FIG. 22 illustrates the angular offset at the entrance slit as a function of the position along the slit and across the slit, for the settings according to FIG. 11A and with θ_{xPrio} set to 8°.

FIG. 23 illustrates the position on the multichannel particle detector of charged particles of different energies.

### DETAILED DESCRIPTION OF THE DISCLOSURE

In the following, the invention will be described using illustrative and non-limiting exemplary embodiments, with references to the appended drawings not necessarily drawn to scale. Similar features appearing in different drawings are denoted by the same reference numerals.

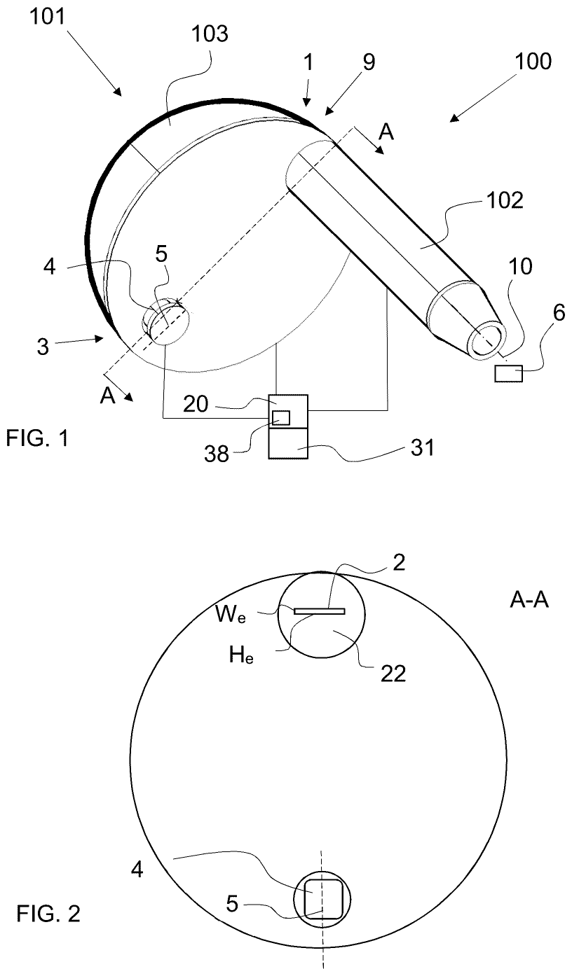

FIG. 1 shows a charged particle spectrometer 100 according to an embodiment. The spectrometer comprises an imaging energy analyser 101. FIG. 2 shows a cross-section of the imaging energy analyser along A-A in FIG. 2. The imaging energy analyser 101 is a hemispherical energy analyser 101 comprising two concentric metallic hemispheres of which only the outer metallic hemisphere 103 is shown. In a hemispherical energy analyser, the first end 1 and the second end 3 are usually essentially in the same plane. The charged particle spectrometer 100 comprises an electrostatic lens system 102, which is arranged to transport charged particles from a sample 6 to the entrance 9 of the hemispherical energy analyser 101. The emission of charged particles from the sample 6 may be achieved by illuminating the sample with electromagnetic radiation. The charged particles enter the hemispherical energy analyser 101 through the entrance 9. The position of the charged particles at the second end 3 is dependent on the kinetic energy of the charged particle at the first end 1 and the magnitude of an electrostatic field applied to the hemispherical energy analyser 101, i.e., between the two metallic hemispheres of which, as mentioned, only the outer metallic hemisphere 103 is shown. Hemispherical energy analysers and their function are well-known in the technical field and will not be explained in more detail. An at least two-dimensional multichannel particle detector 4 is arranged at the second end 3 of the hemispherical energy analyser 101, wherein the multichannel particle detector 4 has multiple detection channels. The dashed line 5 indicates the radial direction of the hemispherical energy analyser 101. The position of the charged particles along the dashed line 5 on the multichannel particle detector 4 is dependent on the kinetic energy of the charged particles at the first end 1 and the magnitude of a voltage applied to the hemispherical energy analyser 101. An entrance slit 2 is arranged at the entrance 9 for selecting the charged particles that enter the hemispherical energy analyser 101. The entrance slit 2 has a main direction of extension along the x-axis. The charged particle spectrometer 100 comprises an electrostatic lens system 102, having an optical axis 10, which is arranged to transport charged particles from a sample 6 to the entrance 9 of the hemispherical energy analyser 101. The electrostatic lens system 102 comprises at a first end 11 a first lens element 12 arranged to face the sample and at a second end 13 a last lens element 14 arranged to face the entrance 9 of the hemispherical energy analyser 101. The first lens element 12 comprises an aperture 40 through which charged particles from the sample 6 may enter the electrostatic lens system 102.

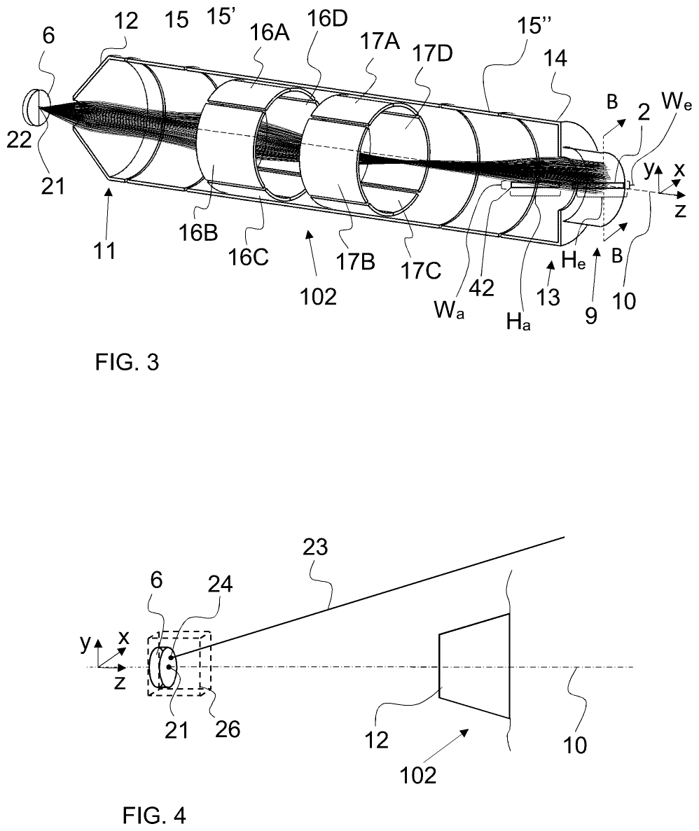

The electrostatic lens system 102 shown in FIG. 3 also comprises three intermediate lens elements 15, 15′, 15″. The number of lens elements in the electrostatic lens system 102 may vary depending on the design, but usually has at least three lens elements.

According to this first embodiment, the electrostatic lens system also comprises, within the intermediate lens element 15′, a first deflector 16A/16C, 16B/16D, operable to cause deflection of the charged particles in a first direction (x, y), perpendicular to the optical axis 10 of the lens system before the entrance of the hemispherical energy analyser 101, and a second deflector 17A/17C, 17B/17D, operable to cause deflection of the charged particles in a direction (x, y) perpendicular to the optical axis 10, at least a second time before the entrance of the hemispherical energy analyser 101. The first deflector comprises four deflector elements, 16A, 16B, 16C, 16D. Similarly, the second deflector comprises four deflector elements 17A, 17B, 17C, 17D. By applying a voltage to opposite pairs of deflector elements 16A, 16B, 16C, 16D, 17A, 17B, 17C, 17D, the direction of the charged particles may be affected. The entrance slit has a width Wₑ in the y-direction and a height He in the x-direction.

The charged particle spectrometer 100 also comprises a control unit 20 configured to control the voltages to the hemispherical energy analyser 101 and the electrostatic lens system 102. The control unit 20 comprises a processor 38, which is configured to execute a computer program. The computer program comprises instructions which, when executed by the processor, configures the control unit to control the operation of the voltages to the spectrometer according to this description.

The charged particle spectrometer 100 is operable in an angular mode in which charged particles from an emission spot 21 are imaged onto an imaging plane 22 at the position of the entrance slit 2 along the optical axis 10. The positions of the charged particles in the imaging plane 22 is dependent on the emission angle of the charged particles from the emission spot point and the voltages applied to the electrostatic lens system. The voltages on the first deflector 16A/16C, 16B/16D and the second deflector 17A/17C, 17B/17D affects the position of the charged particles at the imaging plane 22. However, the effect of the voltages on the first deflector 16A/16C, 16B/16D and the second deflector 17A/17C, 17B/17D is dependent on the voltages on the other lens elements 12, 14, 15, 15′, 15″.

FIG. 4 shows schematically the first lens element 12 of the electrostatic lens system 102 and the optical axis 10 of the electrostatic lens system 102. Also shown in FIG. 4 is a beam 23 of incident radiation, which hits the sample 6 in an emission spot 24. The incident radiation may be, e.g., synchrotron radiation or laser light. The size of the emission spot 24 is dependent on the width of the beam 23. For performing spatially-resolved ARPES it is desirable to have the emission spot smaller than 10 μm. Also shown in FIG. 4 is a zero nominal spatial position of the emission spot 21 which is the position of the nominal spatial position of the electrostatic lens with no voltages applied to the first deflector 16A/16C, 16B/16D and the second deflector 17A/17C, 17B/17D and with a nominal setting of the voltages to the different lens elements 12, 14, 15, 15′, 15″. As can be seen in FIG. 4, the position of the emission spot 24 does not coincide with the position of the zero nominal spatial position 21. The positions of the emission spot 24 and the zero nominal spatial position 21 in FIG. 4 is the result after mechanical alignment of the charged particle spectrometer 100, the beam 23, and the sample 6. It is sometimes very difficult to align the beam 23 with the zero nominal spatial position 21 and the sample 6, such that the emission spot 24 is at the zero nominal spatial position 21. This is especially the case when the source of the beam 23 is a synchrotron. The lens elements 12, 14, 15, 15′, 15″ are preferably rotationally symmetric.

The dashed box 26 in FIG. 4 illustrates the region within which the nominal spatial position of the emission spot may be moved by adjusting the voltages applied to the electrostatic lens system 102. Adjustments are predominantly governed through lens deflector excitations. The set of voltages for a specific nominal spatial position may be calculated. Thus, it is possible to move the zero nominal spatial position to the position of the emission spot 24. The control unit 20 is configured to receive a setting point from a user, comprising a first parameter, which defines a spatial position in a first spatial dimension in relation to the zero nominal spatial position 21, and to control the nominal spatial position of the emission spot to the spatial position defined by the setting point by controlling the voltages to the electrostatic lens system 102. In this way the zero nominal spatial position may be moved. In order to move the nominal spatial position to the position of the emission spot 24 different methods may be used, which will be described in more detail below. One method may comprise small movements of the nominal spatial position followed by relevant measurements of the charged particles, until it is determined that the nominal spatial position is in the position of the emission spot 24.

The first end 11 of the electrostatic lens system is some distance from the sample and thus from the emission spot 24. The electrostatic field between the sample and the first end 11 of the lens system 102 is preferably small enough not to induce any significant lens effect. The distance between the sample 6 and the first lens element 12 is commonly denoted the working distance WD. The aperture 40 in the first lens element 12 serves as a geometrical filter which simply selects the accepted solid angle into the electrostatic lens system 102 based on the radius of the aperture 40 and the working distance WD. A generous working distance WD allows for sample rotation, both from a simple mechanical point of view but also from electrostatic field coupling point of view. This is especially important when cryogenic shields around the sample are used. From other design perspectives, however, a relatively small working distance WD is preferred, partly because it allows for reasonable radii of the lens elements 12, 14, 15, 15′, 15″, even for large acceptance angles. The electrostatic lens is set up for a preferred WD.

The electrostatic lens system 102 according to the described embodiment is to be operated in angular mode. That is, the lens elements of the electrostatic lens system 102 are excited such that a Fourier plane of the emission spot is produced at a desired position along the optical axis 10. The Fourier plane (or subsequently the measured angular distribution) is related to the optical axis of the electrostatic lens system 102. The physical properties of the sample 6, however, are related to the sample surface normal. Conversion into physical properties for interpretation may be performed by means of data post-processing, but this conversion will not be further described here.

The entrance slit 2 is positioned in the Fourier plane, which is positioned downstream of the last lens element 14. In the described embodiment, the last lens element 14 is on the same potential as the entrance slit 2. Wₑ will refer to the potential on the last lens element 14 as the acceleration potential. Such design allows for a field free region between the last lens element 14 and the entrance slit 2. As the entrance slit 2 is non-rotationally symmetric, it is preferable not to have an electric field in said region.

In the below described embodiments, the properties of the hemispherical energy analyser designed with a 200 mm mean radius have been verified using simulation software. The geometry and boundary conditions have been designed such that the performance and general behaviour are similar to those given in the literature. Inside of the hemispherical energy analyser, the potentials are commonly referenced to the acceleration potential. Furthermore, the inner and outer hemispheres of the energy analyser are excited such that an electron entering on the optical axis in a direction normal to the slit plane and at a selected pass energy, Eₚ, will follow the constant radius path between the hemispheres and end up on the centre of the detector positioned at 180 degrees spherical deflection (although some offsets may apply depending on design). Hence, for a constant pass energy, the outer sphere, and analogously the inner sphere, will have a constant offset in relation to the acceleration potential. The potentials of the hemispherical energy analyser will vary with the acceleration potential if referenced to the ground potential. A high pass energy will promote throughput, and in many cases also increase the stability of the instrument. A low pass energy will primarily promote high energy resolution.

The hemispherical energy analyser has reasonably good image properties for a constant input energy close to the pass energy and within a few degrees limit of the input beam divergence. In the radial direction, the hemispherical energy analyser is formally an electrostatic prism and highly chromatic. For a 200 mm radius hemispherical energy analyser, the energy dispersion for 1 eV pass energy is 400 mm/eV. In order to conduct measurements efficiently of both high-energy resolution and high angular resolution, a two-dimensional position-sensitive detection system is required. For the geometry of the example, it is reasonable to have a detector being able to record at least 32 mm in the radial direction, while still imaging a full 30 mm slit in the perpendicular direction. This would give an energy window of 0.08 eV. For larger pass energies, the properties would scale linearly, e.g., for 10 eV pass energy the energy dispersion would be 40 mm/eV and energy window 0.8 eV (8% of pass energy).

Electrostatic lenses are inherently chromatic. A reasonable Fourier plane can only be produced at the slit plane within a small energy interval. Additionally, one objective of the lens system is to transport a selected electron having an initial kinetic energy, Eₖ, from the sample to the slit of the hemispherical energy analyser, such that the energy of this electron enters the hemispherical energy analyser with the selected pass energy. The initial kinetic energy, Eₖ, is defined as the kinetic energy of the electron just outside the sample. Since conservative forces govern electrostatic particle optics, the latter task is readily performed by adjusting the acceleration potential accordingly. For example, if the centre of the energy window of interest is at 87 eV, and the pass energy is selected to be 10 eV, the acceleration potential should be set to 10-87=−77 V. Thus, independent on take-off direction and path through the lens system, two electrons starting with the same energy but different directions, will, if entering within the lens front aperture and unless intersecting any mechanical element, enter the slit plane at a common energy. To distinguish the general term Eₖ from the setting of the lens system, the notation E_{kLens} will be used for the setting of the system.

The conservative forces also make the lens settings scalable, therefore a lens setting is commonly stored as its retardation ratio, RR, where RR=E_{kLens}/Eₚ. For example, if a lens setting is found for the first lens, L1, to be 100 V at E_{kLens}=20 eV and Eₚ=10 eV, the solution is scalable to E_{kLens}=100 eV and Eₚ=50 eV with L1=500 V. That is, at RR=2, then L1=10 V/eV.

In an electrostatic lens system, the particles are accelerated or retarded along their path depending on the potential on the individual lens elements. Each individual lens effect is predominantly occurring in the region between two lens elements of different potentials. The number of lens elements needed depends on boundary conditions and design. Usually, as for the example embodiment, the front lens element is on constant ground potential. As discussed above, there is a benefit of having a last lens element on the acceleration potential. For discrete settings, it would be enough to have only one freely adjustable lens element in an intermediate position between the grounded front element and the last element on the acceleration potential. However, in order to realize constant angular dispersion over continuous retardation ratios at least three freely adjustable lens elements are usually deployed. A larger number of lens elements may also increase the possibility to change the angular dispersion and angular focusing properties significantly. The improved flexibility results in an over-determined optimization problem, meaning that for a specific retardation ratio and desired dispersion there are possibly several combinations of the adjustable lens elements that would result in acceptable solutions.

A highly desired property of the instrument is to be able to choose the retardation ratio freely without any singularities or abrupt changes in behaviour. Therefore, in the prior art significant efforts have been made to produce one dimensional lens tables, each expressing a constant angular dispersion property within an interval of possible retardation ratios. For the general case, an analytical expression cannot be found. Therefore, a lens table is commonly divided in numerous discrete calibration points in terms of retardation ratios. Thus, for a strictly increasing series of retardation ratios, each freely adjustable lens element has a series of corresponding potential settings. The term lens table also implies that the tabulated values describe a constant behaviour of some parametrised lens property, in this context predominately the angular dispersion, and that each series of tabulated values is such that potentials for intermediate retardation ratios can be interpolated with standard spline routines without oscillation or overshoot, i.e., having a locally smooth behaviour. The lens table is therefore in this context a set of one-dimensional curves, which together satisfy a set of boundary conditions within a complex optimization problem.

For the hemispherical entrance slit 2, the dimension in the energy dispersive direction (y-direction) is traditionally denoted the width Wₑ (see FIG. 3) of the slit. For high angular and energy resolution, the width of the slit needs to be relatively narrow. The height Hₑ (see FIG. 3) of the slit is in the in the x-direction, and in the present context associated with the angular dispersive direction of the multichannel particle detector 4. The dimension of the height of the slit can be relatively generous, however, due to the imaging properties of the hemispherical energy analyser, some limitations apply. The non-rotational symmetric entrance region into the hemispherical energy analyser can be designed in different ways. For high-resolution applications, it is beneficial to have at least some restriction in the energy dispersive direction, y-direction, before the hemispherical entrance slit 2. The angular offset of the particle trajectory at the entrance slit 2 plane, relative to the plane defined by the optical axis 10 and the x-direction, is traditionally denoted the α-angle.

Control of the α-angle distribution of the subsection of the particle beam entering the entrance slit 2 is of paramount importance for the energy resolution due to the quadratic α-dependence on the final radial detector position for the hemispherical energy analyser (α given in radians for the expression). For very small α-angles and constant energy, the slit will be imaged in the direction associated with the slit width Wₑ. Allowing a larger divergence in this direction will result in an asymmetric broadening of the slit image on the detector plane in the energy dispersive direction, and thereby deteriorate the ultimate energy resolution directly. When the lens is run in imaging mode, or an extended emitter is used when running the lens in angular mode, an aperture slit 42 (see FIG. 3) positioned some distance upstream of the entrance slit 2 is often used to control the beam divergence in the energy dispersive direction. The height Hₐ of the aperture slit 42 is of the same order as the height Hₑ of the entrance slit 2. The width Wₐ of the aperture slit 42 and its offset position upstream the optical axis 10 will determine which trajectories are allowed to enter the entrance slit 2. The aperture slit 42 is commonly paired with, and dependent on, the width Wₑ of the entrance slit 2. The pairing is selected as an optimisation problem between energy resolution and sensitivity (intensity of the measurement). A larger entrance slit 2 width allows for a broader α-angle distribution when seen from a relative loss of energy resolution perspective. Commonly, the user can select from a set of discrete combination pairs.

For angular mode operation from a very small emission spot, the beam distribution on the slit plane becomes essentially locally collimated. Therefore, for a perfectly aligned and well-functioning instrument (without deflection of the angular pattern in the lens), the aperture slit 42 will for many useful settings become redundant. Implementations without the use of an aperture slit 42 exists, or, perhaps more commonly within the present context, a selectable small entrance slit 2 width Wₑ combined with an oversized aperture slit 42 width Wₐ. In the latter case, the aperture slit 42 is implemented mainly for removal of extreme outliers.

After the introduction of the angular deflection method disclosed in the published international patent application WO 2013/133739 A9, also referred to as the method of electronic tilt angle, the need to control the α-angle distribution has become a boundary condition that limits the practical operational range of the instrument. For a general setting, the double deflection system as presented in the example embodiment of the lens, in theory can only guarantee the desired combination of position and direction at the slit plane for one trajectory at the time. The property of a broader distribution, that is, the distribution of the angular pattern aimed at the entrance slit 2 opening within the energy window of the hemispherical energy analyser band pass filter, the properties at the slit plane will have some difference from the ideal behaviour due to chromatic aberrations, spherical aberrations, theoretical boundaries governed by Liouville's theorem, etc. As a result, for some settings there is simply not enough degrees of freedom to control the distribution such that the α-angles are zero for all trajectories aimed at the entrance slit 2. If an aperture slit 42 is used, trajectories aimed at the entrance slit 2 but having too large α-angles will be cut by the aperture slit, and thereby the intensity of the associated portion of the detector image will be cut as well. This has been referred to as the angular cut-off problem. In the case of using an oversized aperture slit, the trajectories entering the entrance slit 2 with too large α-angles will end up on the detector shifted according to the quadratic α-dependence. For a reasonable α-angle, the energy shift can be corrected by software algorithms performing image rectification of the detector image. However, for larger α-angles, the derivative of change simply becomes too large for any reliable high-energy resolution measurements.

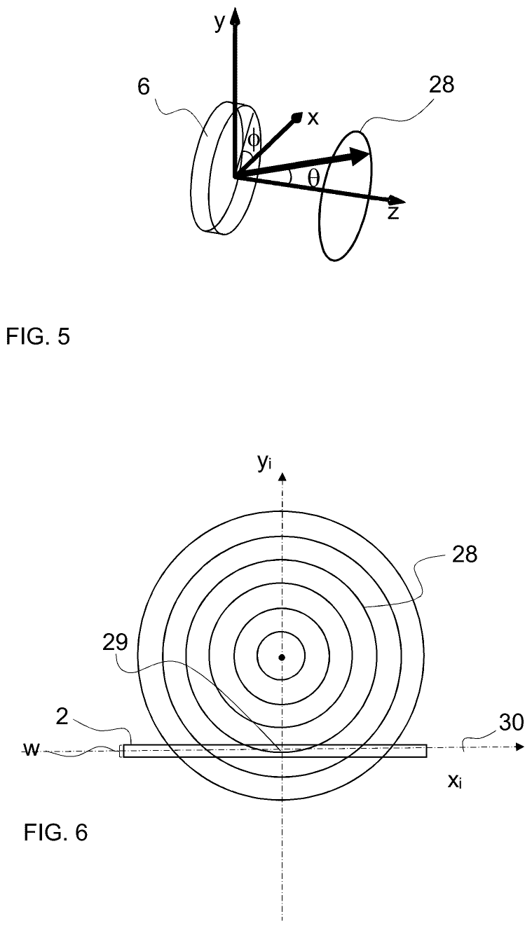

To facilitate the discussion related to electronic tilt angle, a non-traditional but for the purpose very convenient coordinate system has been introduced. The selected coordinate system describes the angular start direction at the object plane as two angular components, θₓ and θ_{y}. In FIG. 5 in conjunction with FIG. 6, the definition is explained with its relation to spherical coordinates (notation according to classical physics). An emission angle θₓ, in the plane defined by the slit direction 30, and the optical axis 10, may be defined as θₓ=θ·cos φ, and an emission angle θ_{y}, in the plane perpendicular to the slit direction 30 may be defined as θ_{y}=θ·sin φ. Movement of the pattern (see FIG. 6) along the yᵢ-axis corresponds to changing the selected angle θ_{y}. To distinguish the general term θ_{y} from the setting of the lens system, the notation θ_{yLens} will be used for the setting of the system. The position in the imaging plane in FIG. 6 can be expressed in the coordinates xᵢ and yᵢ, wherein xᵢ=D_{θ}·θₓ, and yᵢ=D_{θ}·θ_{y}. D_{θ} is the angular dispersion, which in first order approximation can be a linear coefficient.

For the case of electronic deflection of the angular pattern in the direction across the slit (y-coordinate direction), each of the deflector elements, but also possibly some rotational symmetric lens element, will have potential settings dependent on both the retardation ratio and the selected electronic tilt angle (θ_{yLens}). For a pure deflector element, the potential is conveniently referred to the lens element, to which it is associated, such that the selection of no electronic tilt is given by the output 0 V. For example, in a first deflector package 16A, 16B, 16C, 16D, the deflector 16A positioned in the positive y-coordinate direction would be denoted Up1. Then Up1 would be a function of RR and θ_{yLens}, and also scale with pass energy, such that the potential offset would be Up1ₒᵤₜₚᵤₜ=Up1(RR, θ_{yLens})*Ep. Ideally, such lens table is calculated, optimized, and implemented in a two-dimensional fashion, implying that the output potential offset describes a smooth and continuous surface in (RR, θ_{yLens}). Analogous to the lens table previously discussed, such a surface is in the general case possible to represent as a two-dimensional set of calibration points, which are calculated from an optimisation problem, requiring continuity and smoothness of the solution.

It is described in the prior art that a symmetrical arrangement of eight deflector plates can control the direction of a uniform in any desired manner, see for instance U.S. Pat. No. 4,639,602. Furthermore, it is known that for an arrangement of a reduced set of four deflector plates, the quality of the uniform field is slightly reduced for large radii, but for smaller radii, the behaviour is analogous to the system of higher order. Therefore, for a three-dimensional variable space where two of the dimensions are of the same kind and are in the same plane as the lens deflection, the practical implementation can be reduced to a two-dimensional lens table in conjunction with an analytical rotation depending on the azimuthal rotation (φ). Such implementation is valid for spatial deflection in photoelectron spectroscopy where a variable space of (RR, x, y) is denoted as (RR, r, φ), which through the possibility to rotate the field produced by the lens deflector system can be expressed as a lens table in (RR, r) followed by an analytical azimuthal rotation (φ). Analogously, for angular mode operation utilizing electronic tilt angle, a variable space of (RR, θₓ, θₓ) can be expressed as (RR, θ, φ), and therefore most conveniently implemented as a lens table in (RR, θ) followed by an analytical azimuthal rotation (φ).

In a typical measurement utilising the electronic tilt, there is no mechanical movement. Usually, for a fixed E_{kLens} and a fixed Eₚ, the θ_{yLens} is scanned in equidistant angular steps. For each setting, a detector image is recorded. For high resolution and integrity of the mapping, the detector image must be interpreted by slightly non-linear mapping functions. Thus, each pixel of the 2D image will be associated with a triplet (θₓ, θₓ, Eₖ) through a rectification matrix. In prior art, the rectification matrix is dependent on (RR, θ_{yLens}). Predominantly and approximately, Eₖ is linear function in the energy dispersive direction (y) with the value E_{kLens} near the centre of the image, θₓ is a linear function in the direction across the entrance slit 2 (x) with the value zero at x=0, and θ_{y} is equal to θ_{yLens} over the whole detector surface. Therefore, a three-dimensional mapping in (θₓ, θₓ, Eₖ) of the sample is possible through such a scan.

FIG. 5 illustrates in larger detail the sample 6 and shows a coordinate system x, y, z, which will be used to explain directions of emission from the sample. The x-axis is parallel to the direction of extension of the entrance slit 2. The z-direction is parallel to the optical axis of the electrostatic lens system 102. The arrow 27 illustrates electrons that are emitted at an angle θ in relation to the z-axis. The ring 28 illustrates all electrons emitted at an angle θ in relation to the z-axis. As described above, in the angular mode the charged particles from a nominal spatial position are imaged onto an imaging plane 22 at the position of the entrance slit along the optical axis. The position of the charged particles in the imaging plane 22 is dependent on the emission angle of the charged particles from the nominal spatial position and the voltages applied to the electrostatic lens system.

FIG. 6 illustrates the pattern of the charged electrons at the imaging plane 22 for a certain setup of the charged particle spectrometer. The third ring 28 from the outside is an image of the ring 28 in FIG. 5. The centre 29 of the pattern corresponds to electrons emitted from the sample 6 along the optical axis 10. An increasing distance from the centre 29 corresponds to an increasing emission angle θ in relation to the optical axis 10. Each ring corresponds to an increase of the emission angle θ of 2.5°, such that the outermost ring corresponds to an emission angle θ of 15°. Also shown in FIG. 6 is the entrance slit 2, which extends along a slit axis 30, which is parallel to the xᵢ-axis, which in turn is parallel to the x-axis in FIG. 5. The width Wₑ of the entrance slit 2 perpendicular to the slit axis 30 is selected by the user depending on the resolution requirements. A smaller slit will increase the resolution in energy and both angular components (θₓ, θₓ). However, a smaller slit width also decreases the sensitivity (or throughput) of the measurement, and there are additional problems related to having extremely thin slit widths. For spatially-resolved ARPES the selection will generally be such that the emission spot is smaller than the width Wₑ of the entrance slit 2. As can be seen in FIG. 6 the pattern of the charged particles is not centred on the slit but is centred above the entrance slit 2. This is due to settings made by an operator who has chosen to look at electrons having θ_{y} not being zero.

The control unit 20 is provided with a lens table comprising a set of voltages for a number of different spatial positions of the nominal spatial position in said at least one first spatial dimension within a predetermined range for the first spatial parameter and a number of different emission angles, wherein the set of voltages for each spatial position and each emission angle specifies the voltages to be applied on the electrostatic lens system for deflecting charged particles from that spatial position and in that emission angle into the entrance slit 2 of the analyser 101. With such a lens table it is possible to apply the correct voltages to obtain the pattern of the charged particles in the imaging plane 22 as can be seen in FIG. 6, i.e., positioned with the centre of the pattern at different heights. When performing angular spectroscopy, the pattern is moved in the yᵢ-direction perpendicular to the slit axis 30. The lens table may be stored in a memory 31, which may be a part of the control unit 20 or be external to the control unit 20.

An emission angle θₓ in the plane defined by the slit direction 30, and the optical axis 10, may be defined as θₓ=θ·cos φ, and an emission angle θ_{y}, in the plane perpendicular to the slit direction 30 may be defined as θ_{y}=θ·sin φ. Movement of the pattern in FIG. 6 along the yᵢ-axis corresponds to changing the angle θ_{y}. The position in the imaging plane can be expressed in the coordinates xᵢ and yᵢ, wherein xᵢ=D_{θ}·θₓ, and yᵢ=D_{θ}·θ_{y}. For a specific spatial position of the emission spot the set of voltages to be applied to the electrostatic lens system for deflecting charged particles from that spatial position and in a specific emission angle into the entrance slit of the imaging energy analyser 101, is dependent on the spatial position of the nominal spatial position.

A first set of voltages to be applied to the electrostatic lens system, for deflecting charged particles from the nominal spatial position with an emission angle θ_{y}=0 into the entrance slit 2 of the imaging energy analyser 101, may be retrieved from the memory 31. If the position of the emission spot is at the nominal spatial position, as defined above, a second set of voltages to be applied to the electrostatic lens system, for deflecting charged particles with an emission angle θ_{y}=10° into the entrance slit 2 of the imaging energy analyser 101, may be retrieved from the memory 31. If the position of the nominal spatial position is moved to a position x, y, z, in relation to the zero nominal spatial position, a third set of voltages to be applied to the electrostatic lens system, for deflecting charged particles with an emission angle θ_{y}=0, in the plane perpendicular to the slit direction into the entrance slit 2 of the imaging energy analyser 101, may be retrieved from the memory 31. If it is desired to deflect charged particles with an emission angle, in the plane perpendicular to the slit direction 30, θ_{y}=10° from a nominal spatial position in a position x, y, z, into the entrance slit 2 of the imaging energy analyser 101, it is not optimal to superimpose the differences between the third set of voltages and the first set of voltages to the second set of voltages. In other words, the change in voltages for moving the pattern an angle θ_{y}=10° in the plane perpendicular to the slit direction 30, is dependent on the position of the emission spot 24. The differences in the set of voltages for moving the pattern a certain angle along the centre line yᵢ-axis should not be calculated from superposition using the differences in the set of voltages for moving the nominal spatial position of the emission spot to a different position. Thus, for optimal result, if the position of the emission spot is at a position x, y, z, in relation to the zero nominal spatial position, a fourth set of voltages to be applied to the electrostatic lens system, for deflecting charged particles with an emission angle, in the plane perpendicular to the slit direction 30, θ_{y}=10° into the entrance slit 2 of the imaging energy analyser 101, is retrieved from the memory 31.

For some settings of an instrument utilising the scan of the electronic tilt angle, the α-angle distribution becomes very sensitive in the start position of the electrons. For a large emission spot 24, this implies that different areas of the sample may be probed during the scan of the electronic tilt angle. If the sample is homogenous, then this is not a problem. However, for experiments such as spatially-resolved ARPES, where a very small light source is probing a heterogeneous surface, this becomes a major problem since misalignment will result in data acquisition that is either partly quenched due to the angular cut-off problem or uncontrollably shifted in the energy direction. In prior art, for three-dimensional mapping using the electronic tilt angle scan and where high energy and high angular resolution is required, major effort is needed to mechanically align the emitter to the optical axis of the lens and at the correct working distance. Furthermore, in such an experiment, the probed position of the sample is changed by moving the sample under the beam. Ideally, this should not change the alignment between the emission spot 24 and the electrostatic lens 102, but in real experiments, this may be a significant problem, since a mechanical change may induce both mechanical errors and change of the local electrostatic field around the sample for a real non-ideal situation. Furthermore, if, after considerable effort, an interesting area of the sample has been found and properly aligned, changing to a new lens mode may, due to external fields and even small mechanical imperfections of the lens system, result in that the alignment need to be readjusted. Such a situation would render the experiment virtually impossible since the specific probed area will be lost by any mechanical adjustment of the beam 23 or sample 6.

Prior art suggests to mechanically stack a front lens with a single deflector for selecting a small off-axis area of a larger illuminated surface. The mentioned front lens would be positioned before the angular resolving lens incorporating the double deflection system needed for the electronic tilt functionality disclosed in JP2015036670A. Such a solution imposes severe boundary conditions not compatible with large energy windows, as it requires a virtually monochromatic approach for passing the internal aperture separating the lens systems. Furthermore, that the first lens would be able to reset the problem completely is a too rough approximation for highly resolved scanning ARPES from a small spot, since the induced aberrations on the broader distribution in not considered. The invention described in JP2015036670A implicitly teaches an independent lens table for the first lens depending on (RR, r, φ) and a second lens table for the second lens behind the separating aperture to depend on (RR, θ_{yLens}). However, for high order correction and for more general cases, the problem is not separable in this way.

It is known from prior art that for RR>1 the angular cut-off problem generally becomes increasingly severe as the RR increases. This is due to that generally the beam divergence increases with higher retardation. Additionally, increased beam divergence forces the lens system to induce more spherical aberration, which further reduces the quality of the beam distribution. For RR<1 the angular cut-off problem starts to appear in another dimension along the energy axis. This is because the relative energy window increases as the RR becomes smaller. At very low RR, the measurement becomes less efficient, since only the energies close to the E_{kLens} are focused with sufficient quality due to the chromatic problem.

As discussed above, for some settings at higher RR, the angular cut-off problem reduces the operational range of the electronic angular tilt functionality. The example embodiment may not be the theoretical optimal solution for handling this problem. Introducing more poles in the deflector stages would increase the degrees of freedom. However, such implementation comes at a higher cost and will also be associated with the risk of having mechanical errors. A different and more robust approach would facilitate experiments utilizing the combination of small emitters, small slits, and relatively high RR.

Analogously, for very low RR the chromatic problem also reduces the operational range of the electronic angular tilt functionality. Introduction of more deflector poles will therefore not give degrees of freedom suitable to handle the chromatic problem. Reduction of the chromatic problem is traditionally solved by accelerating immersion fields, which is not compatible with highly resolved ARPRES measurements from heterogeneous non-metallic surfaces. A new approach would be interesting for experiments requiring deep energy windows, e.g., pump probe.

For high order correction, the problem is not separable, and therefore a new concept of lens tables including at least three independent variables will need to be introduced.

This implies that the requirement for the calibration points build up in the multidimensional lens table to be at least three-dimensional. The previously described lens table definition still applies, requiring smooth and continuous interpolation within the at least three-dimensional variable space such that the selected part of the angular distribution entering the analyser slit has an essentially constant angular dispersion property.

As will be explained in more detail below the most important spatial dimension to have control over is the nominal spatial position of an emission spot perpendicular to the slit, i.e., along the y-axis. To obtain higher accuracy and operational range compare to prior art the control unit is provided with a lens table comprising a set of individual output voltage settings to be applied on each lens element and each deflector of the electrostatic lens system, wherein at least one voltage setting is defined by at least three parameters. A first parameter defines a nominal spatial position of an emission spot 24 on the sample 6 in one dimension in relation to the optical axis. A second parameter defines an acceleration potential of the electrostatic lens system, and a third parameter defines the direction of emission of the charged particles from the sample 6. The set of voltages for each setting point specifies the voltages to be applied on the electrostatic lens system for deflecting charged particles from the nominal spatial position defined by the first parameter, in the emission angle defined by the second parameter and with an acceleration potential defined by the third parameter, into the entrance slit 2 of the imaging energy analyser 101.

The first parameter defines the position along the y-axis in relation to the zero nominal spatial position. As an example, the first parameter may range from −5 mm to +5 mm in steps of 0.1 mm. The range of the first parameter is typically 1 mm to 20 mm and the different spatial positions are typically 0.01 mm to 0.5 mm apart.

For each setting point in the lens table there is stored a set of voltages to be applied to the different elements of the electrostatic lens. The range of the different emission angles is typically adapted to the acceptance angle of the electrostatic lens. The range of the emission angles in the lens table is typically −15° to +15°, with a step between different emission angles of typically 1°. The steps between different emission angles may of course be smaller or bigger and steps of 0.1° to 5° may be used.

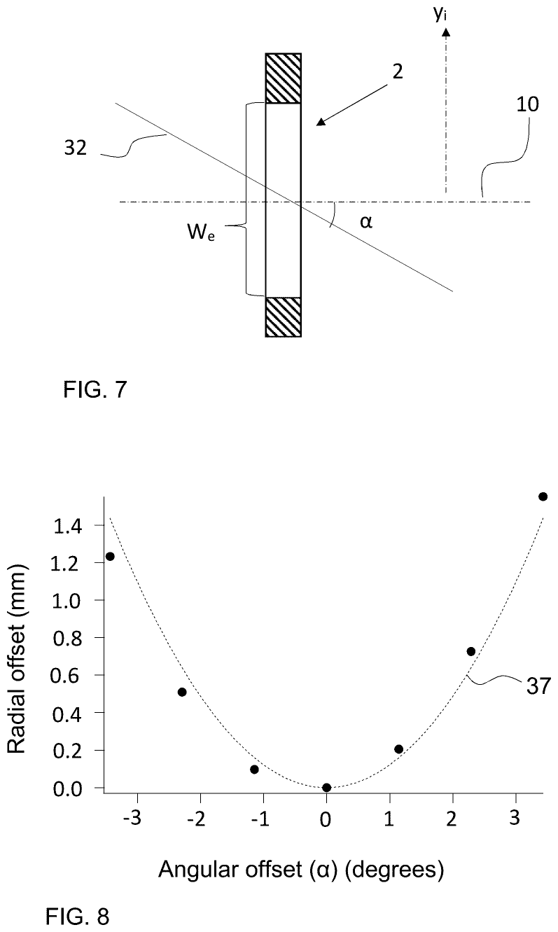

FIG. 7 shows the entrance slit 2 in the cross-section B-B shown in FIG. 3. The trajectory 32 of an electron passing through the entrance slit 2 is shown. The trajectory angle α of the trajectory 32 in relation to the optical axis 10 of the electrostatic lens 102 is also shown. To be able to obtain reliable measurements of the angularly resolved spectra it is important that the trajectory angle α is as small as possible.

FIG. 8 illustrates the radial offset of the charged particles at the multichannel particle detector 4. The dots are based on ray tracing in a model of the spectrometer and the dotted line 37 is based on a well-established analytical expression for hemispherical energy analyser radius of 200 mm. The radial offset is measured along the dashed line 5 in the radial direction of the hemispherical energy analyser 101.

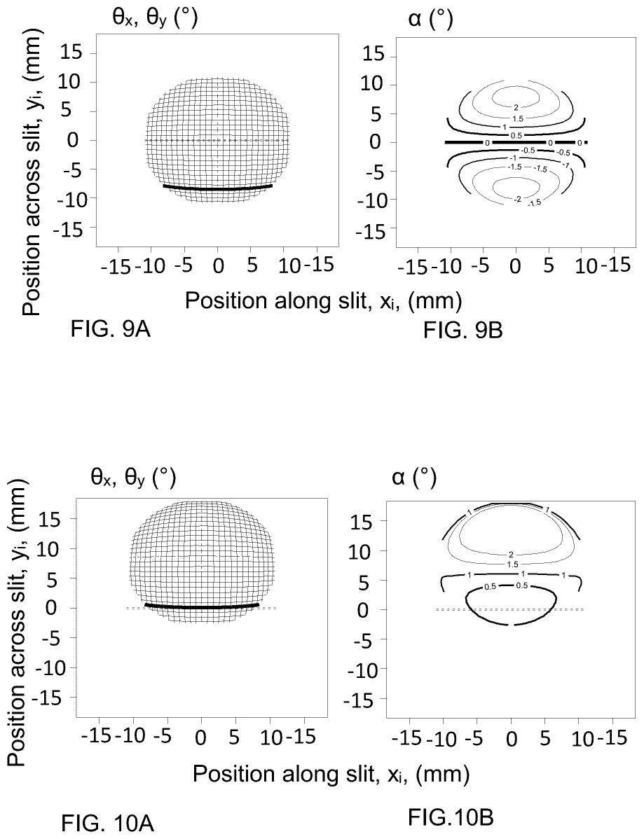

FIG. 9A illustrates a simulation of the angular mapping function on the slit plane for charged particles with different emission angles. The contour mesh has one-degree steps in both θₓ and θ_{y}. Simulated at a retardation ratio of 1.0. Mapping function of take-off angles on the slit plane for optimal alignment and no angular deflection. The angular mesh represents 1° step in both directions. The broken lines represent the geometrical cut by a 0.2 mm slit width. The line representing θ_{y}=100 is drawn with a thicker line, clearly mapped at positions far from the slit opening.

FIG. 9B illustrates the associated resulting trajectory angle α, between the trajectory 32 and the optical axis 10, of the data. The simulations in FIGS. 9A and 9B have been made with RR=1. FIG. 9A illustrates the position of charged particles in the imaging plane 22 wherein the thick line 33 illustrates the emission angle θ_{y}=10°, in the plane perpendicular to the slit direction 30. FIG. 9B illustrates the resulting trajectory angle α at the imaging plane 22. The positions along the slit can be seen in FIG. 3, i.e. along the x-axis is shown on the x-axes of the diagrams, and the positions across the slit, i.e., along the y-axis are shown on the y-axes of the diagram. The entrance slit is positioned at zero on the y-axes. As can be seen in FIG. 9B the resulting angles α are zero at the entrance slit 2 for the emission angle θ_{y}=0°, in the plane perpendicular to the slit direction 30. The resulting α-angle on the slit plane for optimal alignment for the distribution, with the settings of FIG. 9A. The broken lines represent the geometrical cut by a 0.2 mm slit. The distribution passing a small slit will have very small divergence.

FIGS. 10A and 10B illustrates simulations when voltages have been applied to the electrostatic lens such that the emission angle θ_{y}=10°, in the plane perpendicular to the slit direction 30, is positioned on the entrance slit 2. The simulations in FIGS. 10A and 10B have been made with RR=1. FIG. 10A illustrates the position of charged particles in the imaging plane 22 wherein the thick line 33 illustrates the emission angle θ_{y}=10°, in the plane perpendicular to the slit direction 30. Simulated at a retardation ratio of 1.0. Mapping function of take-off angles on the slit plane for optimal alignment and with the lens deflection set for θ_{y}=10°. The angular mesh represents 1° step in both directions. The broken lines represent the geometrical cut by a 0.2 mm slit. The line representing θ_{y}=10° is drawn with a thicker line, mapped on, or in the vicinity of, the slit opening.

FIG. 10B illustrates the resulting associated trajectory angle α at the imaging plane 22. The positions along the slit can be seen in FIG. 3, i.e. along the x-axis is shown on the x-axes of the diagrams, and the positions across the slit, i.e., along the y-axis are shown on the y-axes of the diagram. The entrance slit 2 is positioned at zero on the y-axes. As can be seen in FIG. 10B the resulting angles α are between 0 and 0.50 at the entrance slit 2 for the emission angle θ_{y}=10°, in the plane perpendicular to the slit direction 30, and a position along the slit between −8 mm and +8 mm, representing angular components θₓ along the slit between −10° and +10°. The resulting α-angle on the slit plane for optimal alignment for the distribution, with the settings of FIG. 10A, i.e., θ_{y}=10°. The broken lines represent the geometrical cut by a 0.2 mm slit. The distribution passing a small slit will have some, but small, divergence. At RR=1, the angular deflection mode works nicely at perfect alignment, and there are no major problems when it comes to the α-angle distribution. With reference to FIG. 8 a trajectory angle of 0.5° gives rise to a small radial offset of less than 0.1 mm, which is acceptable for high resolution spectra.

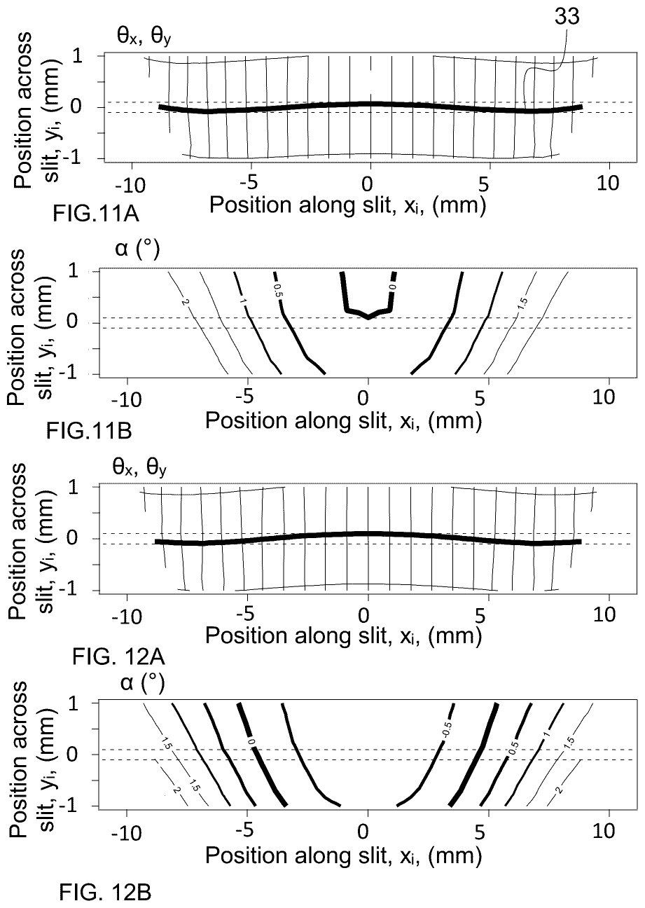

FIG. 11A illustrates in larger detail the position of the charged particles at the entrance slit for simulations where RR=8.7. Mapping function of take-off angles on the slit plane for optimal alignment. The angular mesh represents 1° step in both directions. The line representing θ_{y}=10° is drawn with a thicker line. The 1-by-1 degree pattern is stretched in the y-direction due to the non-planar scale. In the simulations illustrated in FIG. 11A, voltages have been applied to the electrostatic lens such that the emission angle θ_{y}=10°, in the plane perpendicular to the slit direction 30, is positioned on the entrance slit 2 in the angular mode and when the electrostatic lens is optimally aligned. The thick line 33 illustrates charged particles at the entrance slit 2 having θ_{y}=10°. As can be seen in FIG. 11A, it was not possible to image the charged particles with an emission angle θ_{y}=10°, in the plane perpendicular to the slit direction 30, in a perfect straight line in the imaging plane, but the small waveform shown in FIG. 11A is acceptable for a high-resolution spectrum, with moderate software rectification of the mapping function.

FIG. 11B illustrates the angular offset at the entrance slit as a function of the position along the slit and across the slit, for the simulated situation according to FIG. 11A. As can be seen in FIG. 11B the trajectory angle α is close to zero only close to the centre of the entrance slit 2 in the direction along the entrance slit 2. When the position xᵢ along the slit is in the interval −5 mm to +5 mm the trajectory angle α is below 1°. As can be seen in FIG. 8 this results in a radial offset at the multichannel particle detector 4 of less than 0.2 mm, which is still acceptable for a highly resolved spectrum. However, for positions xᵢ along the slit axis 30 below −5 mm or above +5 mm, the trajectory angle α is above 1°. Such a trajectory angle of the charged particles will make it difficult to image the charged particles correctly. The positions xᵢ of −5 mm and +5 mm along the slit axis 30, corresponds to an emission angle θₓ of −6° and +6°, respectively, from the optical axis 10, in the plane defined by the slit axis 30 and the optical axis 10.

FIG. 12A illustrates in larger detail the position of the charged particles at the entrance slit for simulations where RR=8.7. Mapping function of take-off angles on the slit plane for −0.3 mm misalignment in the direction across the slit (y-direction). The positional mapping function is very little effected due to the angular focusing property of the lens mode. In the simulations illustrated in FIG. 12A, voltages have been applied to the electrostatic lens such that the emission angle θ_{y}=10°, in the plane perpendicular to the slit direction 30, is positioned on the entrance slit in the angular mode and when the electrostatic lens is misaligned −0.3 mm in the y-direction, i.e., the emission spot 24 is below the slit along the y-axis. The imaging pattern for the charged particles is similar to the pattern shown in FIG. 11A.

FIG. 12B illustrates the angular offset at the entrance slit as a function of the position along the slit and across the slit, for the simulated situation according to FIG. 12A. The distribution of α-angles changes, although not dramatically in this case.

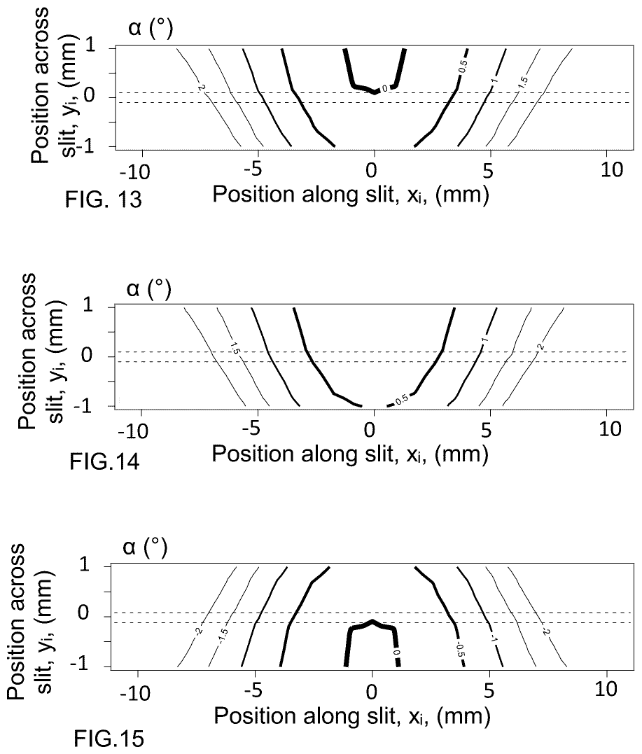

FIG. 13 illustrates the angular offset α at the entrance slit as a function of the position along the slit and across the slit, for the θ_{y} selection and misalignment according to FIG. 12A, when the electrostatic lens is electronically aligned with set of voltages from a lens table. The resulting α-angle on the slit plane for −0.3 mm misalignment in the direction across the slit (y-direction). The electronic alignment parametrisation is set to compensate for the same misalignment. Using the at least three-dimensional dependence according to the invention it is possible to compensate for the misalignment such that the angular offset characteristics is reverted to the characteristics expected from a perfect alignment, as can be seen by comparing with FIG. 11B.

FIG. 14 illustrates the angular offset α at the entrance slit as a function of the position along the slit and across the slit, for the θ_{y} selection and misalignment according to FIG. 12A, when the electrostatic lens is electronically aligned using superposition. The resulting α-angle on the slit plane for −0.3 mm misalignment in the direction across the slit (y-direction). An electronic alignment based on inverse superposition is applied. This correction acts in the right direction but the required accuracy and symmetry is not obtained. By superposition is here meant that the set of voltages to position the nominal spatial position at −0.3 along the y-axis for the emission angle y-axis θ_{y}=0°, in the plane perpendicular to the slit direction 30, are used in superposition with the set of voltages necessary to position the nominal spatial position at zero along the y-axis for the emission angle θ_{y}=10°, in the plane perpendicular to the slit direction 30.

More specifically, a first set of difference voltages may be defined as the set of differences between the set of voltages to position the nominal spatial position at −0.3 along the y-axis for the emission angle θ_{y}=0°, in the plane perpendicular to the slit direction 30, and the set of voltages to position the nominal spatial position at zero along the y-axis for the emission angle θ_{y}=0°, in the plane perpendicular to the slit direction 30. A second set of difference voltages may be defined as the set of differences between the set of voltages to position the nominal spatial position at zero along the y-axis for the emission angle θ_{y}=10°, in the plane perpendicular to the slit direction 30, and the set of voltages to position the nominal spatial position at zero along the y-axis for the emission angle θ_{y}=0°, in the plane perpendicular to the slit direction 30. The from superposition calculated set of voltages would then consist of the sum of the set of voltages to position the nominal spatial position at zero along the y-axis for the emission angle θ_{y}=0°, in the plane perpendicular to the slit direction 30, the first set of difference voltages and the second set of difference voltages.

FIG. 15 illustrates the angular offset at the entrance slit as a function of the position along the slit and across the slit, for simulations where RR=8.7. In the simulations illustrated voltages have been applied to the electrostatic lens such that the emission angle θ_{y}=−10°, in the plane perpendicular to the slit direction 30, is positioned on the entrance slit 2 in the angular mode and when the electrostatic lens is optimally aligned. As can be seen in FIG. 15, the trajectory angle α is close to zero only close to the centre of the entrance slit 2 in the direction along the entrance slit 2. When the position xᵢ along the slit is in the interval −5 mm to +5 mm the trajectory angle α is below 1°. As can be seen in FIG. 8, this results in a radial offset at the multichannel particle detector 4 of less than 0.2 mm, which is still acceptable for a high-resolution spectrum. However, for positions xᵢ along the slit axis 30 below −5 mm or above +5 mm, the trajectory angle α is above 1°. Such a trajectory angle of the charged particles will make it difficult to image the charged particles correctly. The positions xᵢ of −5 mm and +5 mm along the slit axis 30, corresponds to an emission angle θₓ of −6° and +6°, respectively, from the optical axis 10, in the plane defined by the slit axis 30 and the optical axis 10. Due to symmetry, the resulting angular offset characteristics is mirror symmetric to that presented in FIG. 11B.

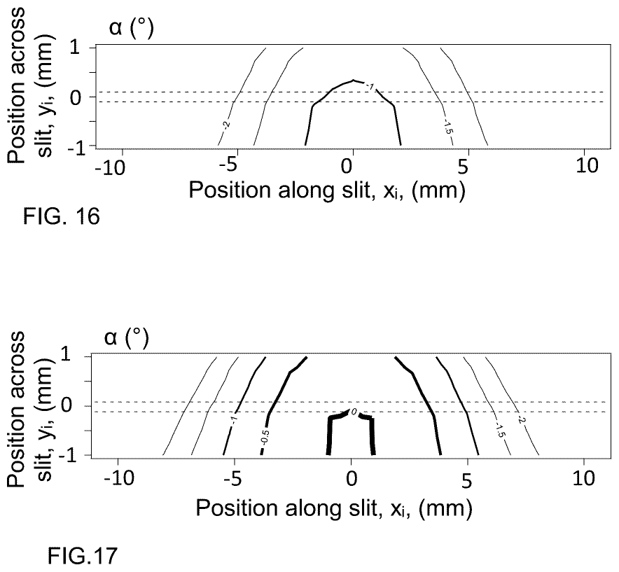

FIG. 16 illustrates the angular offset at the entrance slit as a function of the position along the slit and across the slit, for simulations where RR=8.7. In the simulations illustrated in FIG. 16 voltages have been applied to the electrostatic lens such that the emission angle θ_{y}=−10°, in the plane perpendicular to the slit direction 30, is positioned on the entrance slit in the angular mode and when the electrostatic lens is misaligned −0.3 mm in the y-direction, i.e., the emission spot 24 is 0.3 mm below the slit along the y-axis. The distribution of α-angles is clearly suboptimal. Efficient and trustworthy measurements are not possible without compensation.

FIG. 17 illustrates the angular offset α at the entrance slit as a function of the position along the slit and across the slit, for the settings according to FIG. 16, when the electrostatic lens is electronically aligned with a set of voltages from a lens table. Using the at least three-dimensional dependence according to the invention it is possible to compensate for the misalignment such that the angular offset characteristics is reverted to the characteristics expected from a perfect alignment, as can be seen by comparing with FIG. 15 and the mirrored characteristics from FIG. 11B.

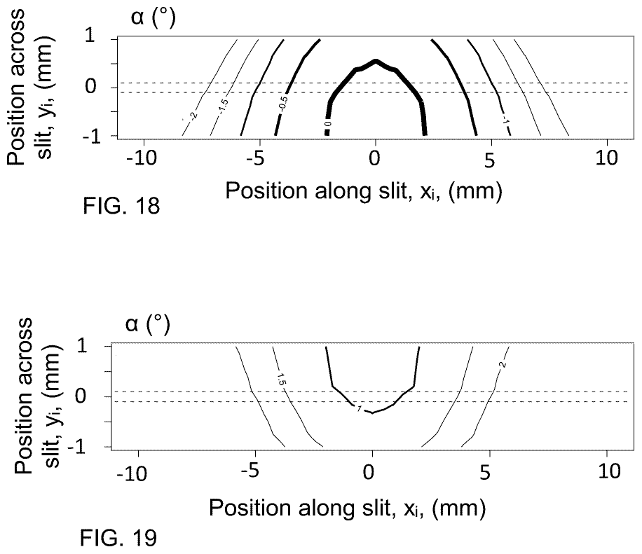

FIG. 18 illustrates the angular offset α at the entrance slit as a function of the position along the slit and across the slit, for the θ_{y} selection and misalignment according to FIG. 16, when the electrostatic lens is electronically aligned using superposition. The correction calculated from superposition acts in the right direction but does not fully recover the α-angle distribution, as can be seen by comparing with FIG. 11B. As can be seen when comparing with FIG. 11B, the compensation using superposition is too low order of compensation to revert the characteristics to that expected from a perfect alignment, and furthermore it is not similar to the mirrored characteristics of FIG. 14. Therefore, when the emission spot is misaligned in the y-direction, even though compensation can be made in the right direction, full symmetry of measurements between negative and positive θ_{y}-selections cannot be achieved when using a superposition method. The superposition will now be illustrated in a numerical example.

The following parameters are set for a first setting: the centre kinetic energy Eₖ of the electrons to study is 87.0 eV, the pass energy Eₚ is 10.0 eV, the x-position of the emission spot in relation to the zero nominal spatial position is 0.0, the y-position of the emission spot in relation to the zero nominal spatial position is 0.0, the position of the emission spot along the optical axis is at the zero nominal spatial position, and the angular deflection is selected to θ_{yLens}=−10.0. The voltages on the lens elements will be given as reference to the ground potential, whilst the voltages on the deflector elements will be references to the lens element 15′. The set of voltages for this setting point is for the three intermediate lens elements 15, 15′, 15″, 729.544 V, 19.702 V, and 334.409 V, respectively. The voltages on the pair of deflector elements 16A, 16C, in the first deflector package 16A, 16B, 16C, 16D, are 15.028 V and −15.028 V, respectively. The voltages on the pair of deflector elements 17A, 17C, in the second deflector package 17A, 17B, 17C, 17D, are −23.430 V and 23.430 V, respectively.

When the y-position of the emission spot is changed to −0.3 mm and θ_{yLens}=0.0, the set of voltages for this setting point is for the three intermediate lens elements 15, 15′, 15″, 729.544 V, 19.702 V, and 334.409 V, respectively. The voltages on the pair of deflector elements 16A, 16C, in the first deflector package 16A, 16B, 16C, 16D, are −0.767 V and 0.767 V, respectively. The voltages on the pair of deflector elements 17A, 17C, in the second deflector package 17A, 17B, 17C, 17D, are 0.247 V, and −0.247 V, respectively.

When the above two sets of voltages are joined using superposition the same voltages are obtained except for the deflector elements. The voltages on the pair of deflector elements 16A, 16C, in the first deflector package 16A, 16B, 16C, 16D, are −14.262 V and 14.262 V, respectively. The voltages on the pair of deflector elements 17A, 17C, in the second deflector package 17A, 17B, 17C, 17D, are −23.183 V, and 23.183 V, respectively.

When using the lens table according to the present invention for θ_{yLens}=−10.0, and the y-position of the emission spot being −0.3 mm, the voltages on the pair of deflector elements 16A, 16C, in the first deflector package 16A, 16B, 16C, 16D, are 14.332 V, and −14.332 V, respectively. These voltages are slightly different from the voltages when using the superposition method according to the above. The voltages on the pair of deflector elements 17A, 17C, in the second deflector package 17A, 17B, 17C, 17D, are −23.114 V, and 23.114 V, respectively. These voltages are slightly different from the voltages when using superposition.

FIG. 19 illustrates the angular offset α at the entrance slit as a function of the position along the slit and across the slit, for simulations where RR=8.7. Simulated at a retardation ratio of 8.7 with the lens deflection set for θ_{yLens}=10°. The resulting α-angle on the slit plane for +0.3 mm misalignment in the direction across the slit (y-direction). The distribution of α-angles is clearly suboptimal. Efficient and trustworthy measurements are therefore not possible. In the simulations illustrated in FIG. 18, voltages have been applied to the electrostatic lens such that the emission angle θ_{y}=10°, in the plane perpendicular to the slit direction 30, is positioned on the entrance slit in the angular mode and when the electrostatic lens is misaligned +0.3 mm in the y-direction, i.e., the emission spot 24 is 0.3 mm above the slit along the y-axis. Due to symmetry the α-angle distribution characteristics is mirror symmetric to the result presented in FIG. 16.

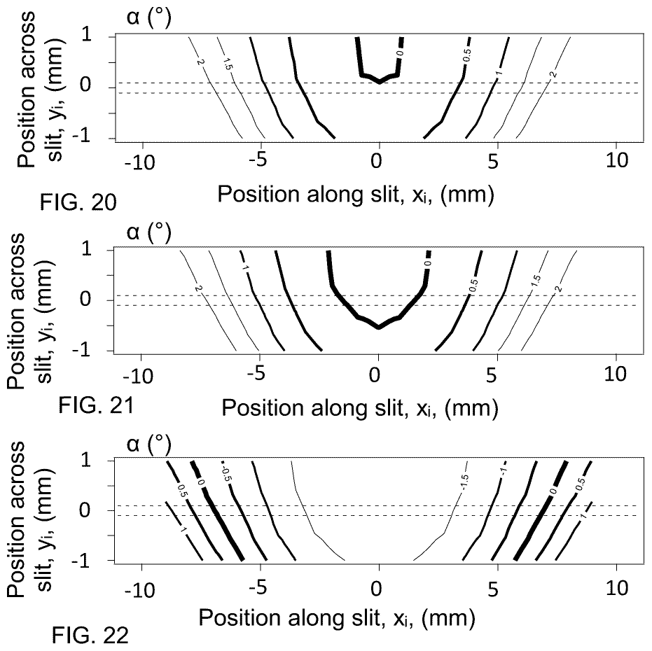

FIG. 20 illustrates the angular offset α at the entrance slit as a function of the position along the slit and across the slit, when the spectrometer is set for detection according to FIG. 19 and when the electrostatic lens is electronically aligned with a set of output voltages settings from the lens table. Using the at least three-dimensional dependence according to the invention it is possible to compensate for the misalignment such that the angular offset characteristics is reverted to the characteristics expected from a perfect alignment, as can be seen by comparing with FIG. 11B. Noteworthy is that FIG. 13, based on the same θ_{yLens} selection but reverse sign of the misalignment, was also reverted to this characteristics, however, the magnitude of the voltages on the deflectors were set differently due to the complex dependence between θ_{yLens} selection and misalignment.

FIG. 21 illustrates the angular offset at the entrance slit as a function of the position along the slit and across the slit, when the spectrometer is set for detection according to FIG. 18 and when the electrostatic lens is electronically aligned using superposition. More specifically, a first set of difference voltages may be defined as the set of differences between the set of voltages to position the nominal spatial position at +0.3 along the y-axis for the emission angle θ_{y}=0°, in the plane perpendicular to the slit direction 30, and the set of voltages to position the nominal spatial position at zero along the y-axis for the emission angle θ_{y}=0°, in the plane perpendicular to the slit direction 30. A second set of difference voltages may be defined as the set of differences between the set of voltages to position the nominal spatial position at zero along the y-axis for the emission angle θ_{y}=10°, in the plane perpendicular to the slit direction 30, and the set of voltages to position the nominal spatial position at zero along the y-axis for the emission angle θ_{y}=0°, in the plane perpendicular to the slit direction 30. The from superposition calculated set of voltages would then consist of the sum of the set of voltages to position the nominal spatial position at zero along the y-axis for the emission angle θ_{y}=0°, in the plane perpendicular to the slit direction 30, the first set of difference voltages and the second set of difference voltages. As can be seen when comparing FIG. 11B, the compensation using superposition is too low order of compensation to revert the characteristics to that expected from a perfect alignment, and furthermore it is not like the characteristics of FIG. 14 where the sign of the misalignment was the opposite.

In the above-described embodiments, only a misalignment in the direction perpendicular to the slit axis 30, have been described. It is, however, possible to take into account a misalignment in the directions along the x-axis and the z-axis shown in FIG. 4.

FIG. 22 illustrates the angular offset α at the entrance slit as a function of the position along the slit and across the slit, for the θ_{yLens} selection and perfect alignment according to FIG. 11A and with θ_{xPrio} set to 8°. This means that the set of voltages applied to the electrostatic lens system are such that the angular offset α at the entrance slit is 0° for charged particles having an emission angle θₓ=8° in the plane defined by the optical axis 10 and the slit axis 30. As stated in relation to FIG. 11B above, it is difficult to image charged particles having a large emission angle θₓ and a large emission angle θ_{y}. However, provided that the set of voltages for θ_{xPrio} is set to 8°, it is still possible to image the charged particles with a large emission angle θₓ in the plane defined by the slit axis 30 and the optical axis 10 and a large emission angle θ_{y} in the plane perpendicular to the slit axis 30. With this setting for θ_{xPrio} the imaging for small emission angles is deteriorated. Thus, by controlling also the parameter θ_{xPrio}, it is possible to record a spectrum for larger intervals for large emission angle θₓ in the plane defined by the slit axis 30 and the optical axis 10 and a large emission angle θ_{y} in the plane perpendicular to the slit axis 30, by setting θ_{xPrio} to an angle different from zero and to merge the, thus, recorded spectrum with a spectrum recorded with θ_{xPrio} set to zero. Using θ_{xPrio} in this way is primarily advantageous when the retardation ratio is large, i.e., when RR is large. For small retardation ratios, i.e. in the order of RR=1 or smaller, the described problem is not as distinct.

For small retardation ratios, another parameter is more important to have control over than the above-described θ_{xPrio} namely the kinetic energy E_{kPrio} of the charged particles at the sample to prioritise. FIG. 19 shows in an enlarged view the multichannel particle detector 4 with the radial direction of the hemispherical deflection indicated by the dashed line 5. The kinetic energy of the charged particles incident on the multichannel particle detector 4 is increasing in the direction of the arrow indicated Eₖ+. In this example the imaging energy analyser 101 (FIG. 1) and the multichannel particle detector 4 are configured such that the energy window of the multichannel particle detector 4 is 8% of the pass energy, i.e., the median energy of the charged particles that passes the entrance slit 2 and hits the multichannel particle detector 4. This means that the highest energy of the charged particles that are incident on the multichannel particle detector 4 has an energy of Eₚ+0.04·Eₚ and the lowest energy of the charged particles that are incident on the multichannel particle detector 4 has an energy of Eₚ−0.04·Eₚ. The energy width divided by the kinetic energy at the sample may be expressed as 0.08·Eₚ/Eₖ. In the following example the assumed retardation ratio RR=0.2. This means that the pass energy Eₚ will be Eₚ=5·Eₖ. The energy window at multichannel particle detector handled by the electrostatic lens system 102 will then be 0.08·5Eₖ=0.4·Eₖ. Thus, assuming that the kinetic energy of the electrons to be examined has a centre energy of about Eₖ=2 eV. Then, the energy window at the multichannel particle detector 4 will be 0.8 eV. This means that the lowest energy of the charged particles to be handled by the electrostatic lens system is 1.6 eV and the highest energy of the charged particles to be handled by the electrostatic lens system is 2.4 eV. Due to the chromatic aberration of the electrostatic lens system, it is difficult to control the trajectories of charged particles within such a large energy window. To this end, the lens table may comprise also an E_{kPrio}. For a specific E_{kPrio} the set of voltages are such that the imaging of charged particles with this energy is prioritised. The non-prioritised energies might not be imaged correctly on the multichannel particle detector. The E_{kPrio} parameter will not change the retardation ratio, but predominantly modulate the deflector voltages.

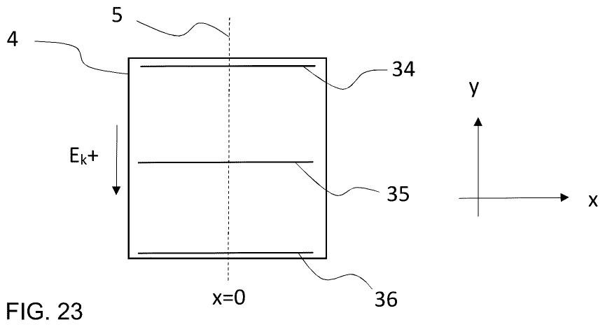

The top line 34 in FIG. 23 illustrates the position of charged particles on the multichannel particle detector with the lowest energy, the middle line 35 in FIG. 19 illustrates the position of charged particles on the multichannel particle detector with the median energy, and the bottom line 36 in FIG. 19 illustrates the position of charged particles on the multichannel particle detector with the highest energy. For the low retardation ratio described above it is only possible to correctly image one of the lines 34, 35, 36. By recording three spectra with different E_{kPrio}, corresponding to the kinetic energies of the charged particles in the three lines 34, 35, 36, and then merging the spectra it is possible to obtain a spectrum for the entire energy window on the multichannel particle detector 4.

Depending on how many parameters that are to be included, the lens table may comprise sets of voltages for different emission angles θ_{y}, in the plane perpendicular to the slit direction 30, for each one of a point in the lens table. The lens table might be multi-dimensional and comprise parameters for the nominal spatial position in three dimensions, the θ_{xPrio}-parameter and the E_{kPrio}-parameter. The nominal spatial position might be defined by an x-position, a y-position and a z-position. Thus, for a specific point in the multi-dimensional lens table there is a set of voltages for a number of different emission angles θ_{y}, in the plane perpendicular to the slit direction 30. The different emission angles θ_{y}, in the plane perpendicular to the slit direction 30, typically range from about −15° to +15°, but may have smaller or larger limits in dependence of, e.g., the acceptance cone of the electrostatic lens system.

The above-described embodiments may be altered in several ways without departing from the scope of the invention, which is limited only by means of the appended claims and their limitations.

1. A charged particle spectrometer operable in angular mode, comprising:
an imaging energy analyser having a first end with an entrance for charged particles, and a second end with an at least two-dimensional multichannel particle detector, wherein at least one entrance slit, extending in a slit direction, is arranged at the entrance for selecting the charged particles to enter the imaging energy analyser,
an electrostatic lens system, extending along an optical axis, arranged to transport charged particles emitted from a sample to the entrance of the imaging energy analyser, the electrostatic lens system comprising at least a first lens element at a first end arranged to face the sample, a last lens element at a second end arranged to face the entrance of the imaging energy analyser, at least one intermediate lens element arranged in-between the first lens element and the last lens element, and at least a first deflector operable to cause deflection of the charged particles in a direction perpendicular to the optical axis of the electrostatic lens system before entry into the imaging energy analyser, and
a control unit configured to control the voltages to be applied to the imaging energy analyser and the electrostatic lens system,
characterised in that
the control unit is provided with a lens table comprising a set of individual output voltage settings to be applied on each lens element and each deflector of the electrostatic lens system, wherein at least one voltage setting is defined by at least three parameters, a first parameter defining a nominal spatial position of an emission spot on the sample in one dimension relative to the optical axis, a second parameter defining an acceleration potential of the electrostatic lens system, and a third parameter defining the direction of emission of the charged particles from the sample, wherein the set of output voltage settings specifies the voltages to be applied on the electrostatic lens system for modulating the deflection of charged particles from the nominal spatial position defined by the first parameter, with an acceleration potential defined by the second parameter and in the emission angle defined by the third parameter, so as to control a selected particle beam trajectory of charged particles to enter into the entrance slit of the imaging energy analyser with a minimised divergence in the direction across the slit at the slit plane.

2. The spectrometer of claim 1, wherein the electrostatic lens system further comprises a second deflector operable to cause deflection of the charged particles in a direction perpendicular to the optical axis of the electrostatic lens system at least a second time before entry into the imaging energy analyser.

3. The spectrometer of claim 1, wherein the output voltage settings are configured in that at least two non-mutually mirror symmetric elements have individual voltage settings, wherein each setting is defined in a non-separable manner by at least said three parameters for controlling at least one selected trajectory associated with the selected condition.

4. The spectrometer of claim 1, wherein a sequence of deflection settings is realised without mechanical movement of any of its components, including the lens elements of the electrostatic lens system, the at least one deflector arrangement and the imaging energy analyser.

5. The spectrometer of claim 1, wherein all deflections of charged particles are performed using electrostatic means.

6. The spectrometer of claim 1, wherein the output voltage settings, for controlling at least one selected trajectory associated with the selected parameters, are defined by a set of continuous functions of the selected parameters.

7. The spectrometer of claim 1, wherein the value of any of the said parameters is continuously selected within upper and lower boundary conditions, wherein the output voltage settings for each element of the electrostatic lens system is a continuous function of the parameters, and wherein the lens table specifies the voltages to be applied on the elements of the electrostatic lens system for controlling at least one selected trajectory associated with the selected parameters.

8. The spectrometer of claim 1, wherein the first parameter defines the nominal spatial position in the direction transverse to the slit direction.

9. The spectrometer of claim 1, wherein the output voltage settings are defined also by a fourth parameter, which defines a nominal spatial position in a second dimension.

10. The spectrometer of claim 9, wherein the fourth parameter defines the nominal spatial position in the direction along the optical axis of the electrostatic lens system.

11. The spectrometer of claim 1, wherein the output voltage settings are defined by at least five parameters of which three parameters define the nominal spatial position of an emission spot on the sample in three dimensions relative to the optical axis and the first lens element.

12. The spectrometer of claim 1, wherein each position on the two-dimensional multichannel particle detector, in addition to any of the previously mentioned parameters of the lens table, is also dependent on an additional parameter defining a shift from the detector centre in the energy direction, and by changing said parameter alone modulates the lens table, such that any energy level within the detector window can be selected to be associated with the selected particle trajectory.

13. The spectrometer of claim 1, wherein each position on the two-dimensional multichannel particle detector, in addition to any of the previously mentioned parameters of the lens table, is also dependent on an additional parameter defining an angular shift from the trajectory associated with the detector centre, the shift being an angular component in the coordinate direction along the slit, and by changing that parameter alone modulates the lens table, such that any angular level within the detector window can be selected to be associated with the selected particle trajectory.

14. A computer program for controlling a charged particle spectrometer operable in angular mode, the spectrometer comprising:
an imaging energy analyser having a first end with an entrance for charged particles, and a second end with an at least two-dimensional multichannel particle detector, wherein at least one entrance slit, extending in a slit direction, is arranged at the entrance for selecting the charged particles to enter the imaging energy analyser,
an electrostatic lens system, extending along an optical axis, arranged to transport charged particles emitted from a sample to the entrance of the imaging energy analyser, the electrostatic lens system comprising at least a first lens element at a first end arranged to face the sample, a last lens element at a second end arranged to face the entrance of the imaging energy analyser, at least one intermediate lens element arranged in-between the first lens element and the last lens element, and at least a first deflector operable to cause deflection of the charged particles in at least a first coordinate direction perpendicular to the optical axis of the electrostatic lens system before entry into the imaging energy analyser, and
a control unit, comprising a processor, configured to control the voltages to be applied to the imaging energy analyser and the electrostatic lens system, characterised in that the computer program further comprises instructions, which, when executed by the processor:
configures the control unit to be provided with a lens table comprising a set of individual output voltage settings to be applied on each lens element and each deflector of the electrostatic lens system, wherein at least one voltage setting is defined by at least three parameters, a first parameter defining a nominal spatial position of an emission spot on the sample in one dimension relative to the optical axis and/or to the first lens element, a second parameter defining an acceleration potential of the electrostatic lens system, and a third parameter defining the direction of emission of the charged particles from the sample, wherein the set of output voltage settings specifies the voltages to be applied on the electrostatic lens system for modulating the deflection of charged particles from the nominal spatial position defined by the first parameter, with an acceleration potential defined by the second parameter and in the emission angle defined by the third parameter, so as to control a selected particle beam trajectory of charged particles to enter into the entrance slit of the imaging energy analyser with a minimised divergence in the direction across the slit at the slit plane.

15. A computer program for controlling a charged particle spectrometer, characterised in that it further comprises instructions, which, when executed on the processor causes the spectrometer to function in accordance with claim 14.
